(19) United States
(12) Patent Application Publication
(10) Pub. No.: US 2024/0213189 A1
(43) Pub. Date: Jun. 27, 2024

(54) POWER AMPLIFICATION HIGH-FREQUENCY CIRCUIT DEVICE

(71) Applicant: Mitsubishi Electric Corporation, Tokyo (JP)

(72) Inventors: Yuta SUGIYAMA, Tokyo (JP); Takeshi OSHIMA, Tokyo (JP); Hidenori ISHIBASHI, Tokyo (JP); Miki KAGANO, Tokyo (JP); Hidenori YUKAWA, Tokyo (JP)

(73) Assignee: Mitsubishi Electric Corporation, Tokyo (JP)

(21) Appl. No.: 18/595,729

(22) Filed: Mar. 5, 2024

Related U.S. Application Data
(63) Continuation of application No. PCT/JP2021/041449, filed on Nov. 11, 2021.

(51) Int. Cl. H01L 23/66; H01L 23/00; H01L 23/498; H01L 23/552; H03F 3/213

(52) U.S. Cl. CPC H01L 23/66; H01L 23/49838; H01L 23/552; H01L 24/16; H01L 24/32; H03F 3/213; H01L 2223/6627; H01L 2223/6655; H01L 2224/16146; H01L 2224/16155; H01L 2224/32146; H01L 2224/32175; H01L 2924/014; H01L 2924/1421; H01L 2924/1423; H03F 2200/451

(57) ABSTRACT

A power amplification high-frequency circuit device includes: an input conversion pin; an output conversion pin; a high-frequency amplifier having an input terminal and an output terminal; a waveguide tube in which an input waveguide tube and an output waveguide tube face each other with a short wall interposed between the input waveguide tube and the output waveguide tube, an upper wall of the input waveguide tube has an input pin insertion hole into which the input conversion pin is inserted while being electrically insulated, an upper wall of the output waveguide tube has an output pin insertion hole into which the output conversion pin is inserted while being electrically insulated, an upper wall has a storage portion having a flat bottom surface, and the high-frequency amplifier is stored in the storage portion with a bottom surface thereof being in close contact with the bottom surface of the storage portion.

### CROSS REFERENCE TO RELATED APPLICATIONS

This application is a Continuation of PCT International Application No. PCT/JP2021/041449 filed on Nov. 11, 2021, which is hereby expressly incorporated by reference into the present application.

### TECHNICAL FIELD

The present disclosure relates to a power amplification high-frequency circuit device that amplifies high-frequency power using a high-frequency amplifier and a waveguide tube.

### BACKGROUND ART

Patent Literature 1 discloses a microwave circuit device including a field effect transistor as an amplifying element and a waveguide tube partitioned into a microwave input side and a microwave output side by a short-circuit partition wall, in which a lower surface (input and output common terminal) of the field effect transistor is in close contact with a base plate that is in close contact with an upper surface of the waveguide tube.

The microwave circuit device disclosed in Patent Literature 1 includes a waveguide tube block that forms a waveguide tube together with a thick metal plate, and further includes a heat dissipation fin attached in close contact with the metal plate in order to dissipate heat from a microwave amplifier module constituted by a field effect transistor or the like.

In addition, the microwave circuit device disclosed in Patent Literature 1 is completely shielded by a metal cover in order to minimize leakage power of a microwave from the amplifier module.

### CITATION LIST

### Patent Literature

Patent Literature 1: JP 5-206710 A

### SUMMARY OF INVENTION

### Technical Problem

The microwave circuit device disclosed in Patent Literature 1 has a problem that heat of a field effect transistor is dissipated from a lower surface of the field effect transistor to a waveguide tube, and a thick metal plate is formed as the waveguide tube and a heat dissipation fin is further attached in close contact with the metal plate in order to dissipate heat from the field effect transistor.

The present disclosure has solved the above problems, and an object of the present disclosure is to obtain a power amplification high-frequency circuit device that easily dissipates heat from a high-frequency amplifier with a simple configuration without disposing a thick metal plate or a heat dissipation fin in a waveguide tube.

### Solution to Problem

A power amplification high-frequency circuit device according to the present disclosure includes: an input conversion pin; an output conversion pin;

a high-frequency amplifier having an input terminal and an output terminal; a waveguide tube including an input waveguide tube, an output waveguide tube, and a short wall, in which the input waveguide tube and the output waveguide tube are disposed in such a way as to face each other with the short wall interposed between the input waveguide tube and the output waveguide tube, an upper wall of the input waveguide tube has an input pin insertion hole into which the input conversion pin is inserted while being electrically insulated in such a manner that a first end of the input conversion pin protrudes inward and a second end of the input conversion pin protrudes outward, an upper wall of the output waveguide tube has an output pin insertion hole into which the output conversion pin is inserted while being electrically insulated in such a manner that a first end of the output conversion pin protrudes inward and a second end of the output conversion pin protrudes outward, an upper wall thereof has a storage portion whose depth from an outer wall surface of the upper wall is deeper than the height of the high-frequency amplifier and which has a flat bottom surface, and the high-frequency amplifier is stored in the storage portion with a bottom surface of the high-frequency amplifier being in close contact with the bottom surface of the storage portion; and a substrate including an insulating substrate having, on a back surface of the insulating substrate, input signal wiring whose first end portion is electrically connected to the input conversion pin and whose second end portion is electrically connected to the input terminal of the high-frequency amplifier, and output signal wiring whose first end portion is electrically connected to the output terminal of the high-frequency amplifier and whose second end portion is electrically connected to the output conversion pin, wherein a width of the storage portion in a direction of a straight line on which the input terminal and the output terminal of the high-frequency amplifier are disposed is set to a length including the input pin insertion hole into which the input conversion pin is inserted and which is formed in the upper wall of the input waveguide tube, and the output pin insertion hole into which the output conversion pin is inserted and which is formed in the upper wall of the output waveguide tube, the input signal wiring and the output signal wiring are disposed on the back surface of the insulating substrate, the input conversion pin is a spring probe which is inserted into the input pin insertion hole into which the input conversion pin is inserted and which is formed in the upper wall of the input waveguide tube, and is fixed to the upper wall of the input waveguide tube, and a distal end of which is brought into close contact with the input signal wiring by an elastic force and electrically connected to the input signal wiring, and the output conversion pin is a spring probe which is inserted into the output pin insertion hole into which the output conversion pin is inserted and which is formed in the upper wall of the output waveguide tube, and is fixed to the upper wall of the output waveguide tube, and a distal end of which is brought into close contact with the output signal wiring by an elastic force and electrically connected to the output signal wiring.

### Advantageous Effects of Invention

According to the present disclosure, since the waveguide tube has the storage portion in which the high-frequency amplifier is stored with a bottom surface of the high-frequency amplifier being in close contact with a bottom surface of the storage portion, heat from the high-frequency amplifier can be dissipated with a simple configuration.

### BRIEF DESCRIPTION OF DRAWINGS

FIG. 1 is a top view illustrating a power amplification high-frequency circuit device according to a first embodiment.

FIG. 2 is a cross-sectional view cut along A-A in FIG. 1.

FIG. 3 is a cross-sectional view cut along B-B in FIG. 2.

FIG. 4 is a cross-sectional view cut along C-C in FIG. 2.

FIG. 5 is a top view illustrating a power amplification high-frequency circuit device according to a second embodiment.

FIG. 6 is a cross-sectional view cut along A-A in FIG. 5.

FIG. 7 is a cross-sectional view cut along B-B in FIG. 6.

FIG. 8 is a cross-sectional view cut along C-C in FIG. 6.

FIG. 9 is a top view illustrating a power amplification high-frequency circuit device according to a third embodiment.

FIG. 10 is a cross-sectional view cut along A-A in FIG. 9.

FIG. 11 is a cross-sectional view cut along B-B in FIG. 10.

FIG. 12 is a cross-sectional view cut along C-C in FIG. 10.

FIG. 13 is a top view illustrating a power amplification high-frequency circuit device according to a fourth embodiment.

FIG. 14 is a cross-sectional view cut along A-A in FIG. 13.

FIG. 15 is a top view illustrating a power amplification high-frequency circuit device according to a fifth embodiment.

FIG. 16 is a cross-sectional view cut along A-A in FIG. 15.

FIG. 17 is a cross-sectional view cut along B-B in FIG. 16.

FIG. 18 is a cross-sectional view cut along C-C in FIG. 16.

### DESCRIPTION OF EMBODIMENTS

### First Embodiment

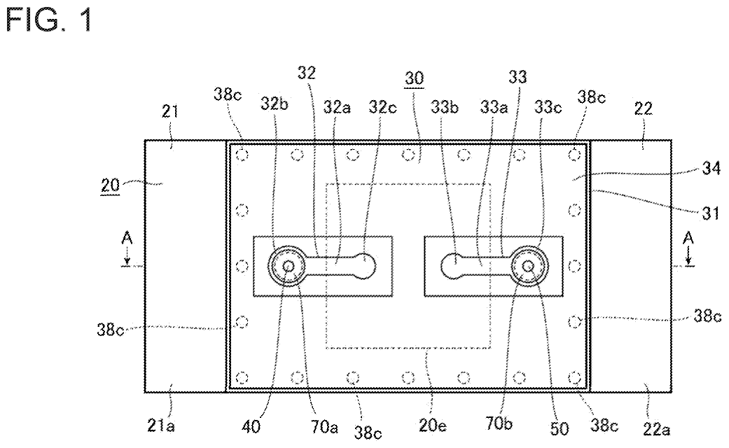

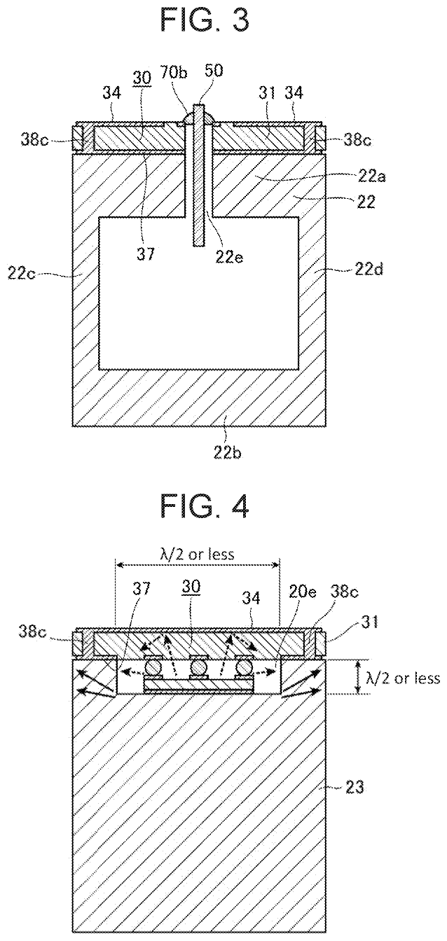

A power amplification high-frequency circuit device according to a first embodiment will be described with reference to FIGS. 1 to 4.

The power amplification high-frequency circuit device according to the first embodiment includes a high-frequency amplifier 10, a waveguide tube 20, a substrate 30, an input conversion pin 40, and an output conversion pin 50.

The high-frequency amplifier 10 has an input terminal 11, an output terminal 12, and an input and output common terminal 13.

The input terminal 11 is disposed on a first end side of one main surface, and the output terminal 12 is disposed on a second end side of the one main surface.

The input terminal 11 and the output terminal 12 are disposed on the one main surface while being electrically insulated from each other on a straight line parallel to a tube axis of the waveguide tube 20.

The input and output common terminal 13 is a metal layer disposed on the entire other main surface and having excellent heat dissipation.

The high-frequency amplifier 10 is, for example, a field effect transistor (FET) as a high-frequency amplifying element or a high-frequency amplifying IC including an FET.

When the high-frequency amplifier 10 is, for example, an FET, the input terminal 11 is a gate terminal, the output terminal 12 is a drain terminal, and the input and output common terminal 13 is a source terminal.

The gate terminal is set to a gate bias voltage by a gate bias circuit (not illustrated), the drain terminal is connected to a power supply potential via a drain bias circuit (not illustrated) and power is supplied thereto, and the source terminal is set to a ground potential.

The waveguide tube 20 includes an input waveguide tube 21, an output waveguide tube 22, and a short wall 23, and the input waveguide tube 21 and the output waveguide tube 22 are disposed in such a way as to face each other with the short wall 23 interposed therebetween and are integrally constituted.

The waveguide tube 20 is made of metal and set to a ground potential.

The input waveguide tube 21 has an upper wall 21a, a lower wall 21b, and a pair of side walls 21c and 21d. The output waveguide tube 22 has an upper wall 22a, a lower wall 22b, and a pair of side walls 22c and 22d. The input waveguide tube 21 and the output waveguide tube 22 each have a quadrilateral cross section, and tube axes thereof coincide with each other.

The short wall 23 is interposed between a first end of the input waveguide tube 21 and a second end of the output waveguide tube 22, and has a quadrilateral plate shape.

An upper wall 20a of the waveguide tube 20 refers to a set of the upper wall 21a of the input waveguide tube 21, the upper wall 22a of the output waveguide tube 22, and an upper portion of the short wall 23.

A lower wall 20b of the waveguide tube 20 refers to a set of the lower wall 21b of the input waveguide tube 21, the lower wall 22b of the output waveguide tube 22, and a lower portion of the short wall 23.

As for a pair of side walls 20c and 20d of the waveguide tube 20, the side wall 20c refers to a set of the side wall 21c of the input waveguide tube 21, the side wall 22c of the output waveguide tube 22, and one of a pair of side portions of the short wall 23, and the side wall 20d refers to a set of the side wall 21d of the input waveguide tube 21, the side wall 22d of the output waveguide tube 22, and the other of the pair of side portions of the short wall 23.

The upper wall, the lower wall, and the pair of side walls are given names for convenience of description, and the upper wall does not necessarily refer to only a wall located at an upper portion.

Note that a waveguide of the input waveguide tube 21 and a waveguide of the output waveguide tube 22 each have a rectangular cross section in a direction orthogonal to a tube axis, and the upper wall 20a and the lower wall 20b of the waveguide tube 20 are located on a long side, and the pair of side walls 20c and 20d of the waveguide tube 20 are located on a short side.

The upper wall 21a of the input waveguide tube 21 has an input pin insertion hole 21e into which the input conversion pin 40 is inserted while maintaining an electrical insulating state from the upper wall 21a.

A first end of the input conversion pin 40 protrudes inward of the upper wall 21a, and a second end thereof protrudes outward of the upper wall 21a.

The upper wall 22a of the output waveguide tube 22 has an output pin insertion hole 22e into which the output conversion pin 50 is inserted while maintaining an electrical insulating state from the upper wall 22a.

A first end of the output conversion pin 50 protrudes inward of the upper wall 22a, and a second end thereof protrudes outward of the upper wall 22a.

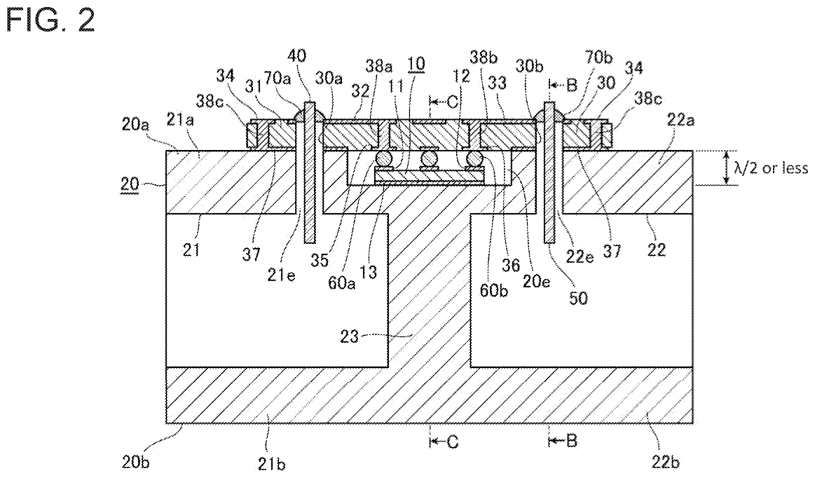

As illustrated in FIG. 2, the upper wall 20a of the waveguide tube 20 has a storage portion 20e whose depth from an outer wall surface of the upper wall 20a is deeper than the height of the high-frequency amplifier 10 and which has a flat bottom surface, at a central portion thereof.

The storage portion 20e is a recess having a recessed structure recessed downward from the outer wall surface of the upper wall 20a.

The storage portion 20e is a recess formed of a space in which a bottom surface communicating with an upper portion of the short wall 23, an upper portion of the upper wall 21a of the input waveguide tube 21 on a second end side, and an upper portion of the upper wall 22a of the output waveguide tube 22 on a first end side is a flat surface, and a plane, a lateral cross section, and a longitudinal cross section are quadrilateral.

The storage portion 20e is located between the input conversion pin 40 and the output conversion pin 50.

The depth of the storage portion 20e is equal to or less than ½ of a wavelength λ of a frequency of a signal input to the high-frequency amplifier 10 (hereinafter, referred to as a signal frequency).

The width of the storage portion 20e in a longitudinal direction is longer than the width of the high-frequency amplifier 10 in the longitudinal direction and is equal to or less than ½ of a wavelength λ of a signal frequency.

The longitudinal direction is a direction orthogonal to a straight line on which the input terminal 11 and the output terminal 12 are disposed on a plane, that is, a direction orthogonal to the tube axis of the waveguide tube, and is a longitudinal direction in FIG. 1.

The width of the storage portion 20e in a lateral direction is longer than the width of the high-frequency amplifier 10 in the lateral direction, and is preferably equal to or less than ½ of a wavelength λ of a signal frequency.

The high-frequency amplifier 10 is stored in the storage portion 20e while the input and output common terminal 13 disposed on the entire other main surface is closely fixed to the bottom surface of the storage portion 20e of the waveguide tube 20.

The entire other main surface of the high-frequency amplifier 10 and the bottom surface of the storage portion 20e are brought into close contact with each other with a high thermal conductive adhesive, solder, a high thermal conductive sintered material, or a high heat dissipation sheet.

As a result, heat generated by the high-frequency amplifier 10 is efficiently dissipated from the entire other main surface to the waveguide tube 20 via the bottom surface of the storage portion 20e.

Note that a material that alleviates a stress generated by a thermal linear expansion difference between the high-frequency amplifier 10 and the waveguide tube 20 may be disposed between the entire other main surface of the high-frequency amplifier 10 and the bottom surface of the storage portion 20e.

The substrate 30 includes an insulating substrate 31 having, on a front surface thereof, an input signal wiring layer 32, an output signal wiring layer 33, and a front surface side shield layer 34 set to a ground potential, and having, on a back surface thereof, an input signal land 35, an output signal land 36, and a back surface side shield layer 37 set to a ground potential.

As illustrated in FIG. 2, the substrate 30 has an input pin insertion hole 30a communicating with the input pin insertion hole 21e formed in the upper wall 21a of the input waveguide tube 21, and an output pin insertion hole 30b communicating with the output pin insertion hole 22e formed in the upper wall 22a of the output waveguide tube 22.

The input signal wiring layer 32 is disposed on a straight line parallel to a straight line on which the input terminal 11 and the output terminal 12 of the high-frequency amplifier 10 are disposed, has a land 32b surrounding an upper end opening of the input pin insertion hole 30a at a first end, has a land 32c at a position facing the input terminal 11 of the high-frequency amplifier 10 at a second end, and has a wiring layer 32a linearly connecting the land 32b to the land 32c.

The output signal wiring layer 33 is disposed on a straight line on which the input signal wiring layer 32 is disposed along a straight line on which the input terminal 11 and the output terminal 12 of the high-frequency amplifier 10 are disposed, has a land 33b at a position facing the output terminal 12 of the high-frequency amplifier 10 at a first end, has a land 33c surrounding an upper end opening of the output pin insertion hole 30b at a second end, and has a wiring layer 33a linearly connecting the land 33b to the land 33c.

The length of the output signal wiring layer 33 is preferably a minimum wiring length required for matching between the output terminal 12 of the high-frequency amplifier 10 and the output waveguide tube 22, that is, a matching circuit.

As described above, by setting the length of the output signal wiring layer 33 to a minimum wiring length required for a matching circuit, a loss in the output signal wiring layer 33 can be reduced.

As illustrated in FIG. 1, the front surface side shield layer 34 is a metal layer electrically insulated from the input signal wiring layer 32 and the output signal wiring layer 33, surrounding the input signal wiring layer 32 and the output signal wiring layer 33, and extending to a peripheral portion of the insulating substrate 31.

The input signal land 35 is disposed at a position facing the input terminal 11 of the high-frequency amplifier 10, and is electrically and mechanically connected to the input terminal 11 with a solder ball 60a.

The input signal land 35 and the land 32c of the input signal wiring layer 32 are electrically connected to each other by a through hole 38a.

The output signal land 36 is disposed at a position facing the output terminal 12 of the high-frequency amplifier 10, and is electrically and mechanically connected to the output terminal 12 with a solder ball 60b.

The output signal land 36 and the land 33b are electrically connected to each other by a through hole 38b.

The back surface side shield layer 37 is a metal layer surrounding the storage portion 20e and extending to a peripheral portion of the insulating substrate 31.

The back surface side shield layer 37 is in close contact with an outer wall surface of the upper wall 20a of the waveguide tube 20 excluding the storage portion 20e.

The back surface side shield layer 37 and the outer wall surface of the upper wall 20a of the waveguide tube 20 are brought into close contact with each other with an adhesive, solder, a sintered material, or a sheet.

The substrate 30 is closely fixed to the outer wall surface of the upper wall 20a of the waveguide tube 20. As a result, a space formed by the storage portion 20e is sealed by the substrate 30 and the upper wall 20a of the waveguide tube 20.

The front surface side shield layer 34 and the back surface side shield layer 37 are electrically connected to each other by a plurality of through holes 38c formed along four sides in a peripheral portion of the insulating substrate 31.

The input conversion pin 40 is inserted into the input pin insertion hole 30a and the input pin insertion hole 21e formed in the upper wall 21a of the input waveguide tube 21 from an upper end opening of the input pin insertion hole 30a of the substrate 30 while being electrically insulated from the substrate 30 and the upper wall 21a of the input waveguide tube 21, and a first end of the input conversion pin 40 protrudes into the input waveguide tube 21.

A second end portion of the input conversion pin 40 is electrically and mechanically connected to the land 32b of the input signal wiring layer 32 with a solder 70a.

The output conversion pin 50 is inserted into the output pin insertion hole 30b and the output pin insertion hole 22e formed in the upper wall 22a of the output waveguide tube 22 from an upper end opening of the output pin insertion hole 30b of the substrate 30 while being electrically insulated from the substrate 30 and the upper wall 22a of the output waveguide tube 22, and a first end of the output conversion pin 50 protrudes into the output waveguide tube 22.

A second end portion of the output conversion pin 50 is electrically and mechanically connected to the land 33c of the output signal wiring layer 33 with a solder 70b.

Next, an operation of the power amplification high-frequency circuit device according to the first embodiment configured as described above will be described.

An electromagnetic wave incident on a first end opening of the input waveguide tube 21 and propagated in a transverse electric 01 (TE01) mode is converted from an electromagnetic field mode of the waveguide tube 20 to a transverse electromagnetic (TEM) mode through the input conversion pin 40, and is transmitted as a high-frequency signal to the input terminal 11 of the high-frequency amplifier 10 via the input signal wiring layer 32 and the through hole 38a in the substrate 30, and the solder ball 60a.

The signal input to the input terminal 11 of the high-frequency amplifier 10 is amplified by the high-frequency amplifier 10, and is output as an amplified high-frequency signal from the output terminal 12 of the high-frequency amplifier 10.

The amplified high-frequency signal output from the output terminal 12 of the high-frequency amplifier 10 is transmitted to the output conversion pin 50 via the solder ball 60b, and the through hole 38b and the output signal wiring layer 33 in the substrate 30.

The high-frequency signal transmitted to the output conversion pin 50 is converted from the TEM mode to the TE01 mode of the waveguide tube 20 by the output conversion pin 50, and is output from a second end opening of the output waveguide tube 22.

The front surface side shield layer 34 and the back surface side shield layer 37 in the substrate 30 are set to a ground potential by the plurality of through holes 38c, and the back surface side shield layer 37 and the outer wall surface of the upper wall 20a of the waveguide tube 20 are in close contact with each other. As a result, the waveguide tube 20 is also set to a ground potential.

In addition, the bottom surface of the storage portion 20e formed in the waveguide tube 20 and the input and output common terminal 13 of the high-frequency amplifier 10 are also set to a ground potential.

Meanwhile, heat generated by a loss of a large amount of power due to an amplification operation of the high-frequency amplifier 10 is transmitted from the metal layer disposed on the entire other main surface constituting the input and output common terminal 13 of the high-frequency amplifier 10 to the bottom surface of the storage portion 20e formed in the waveguide tube 20 in close contact with the metal layer as indicated by a solid arrow in FIG. 4.

The heat transmitted to the bottom surface of the storage portion 20e is transmitted to the upper wall 20a including the thickness of the upper wall 20a constituting a side face of the storage portion 20e from the bottom surface of the storage portion 20e, and is dissipated to outside air from both side faces of the upper wall 20a.

That is, since the high-frequency amplifier 10 is stored in the storage portion 20e while the other main surface of the high-frequency amplifier 10 is in close contact with the bottom surface of the storage portion 20e, the heat generated from the high-frequency amplifier 10 can be dissipated from the upper wall 20a of the waveguide tube 20 to outside air with a simple configuration.

In addition, since the high-frequency amplifier 10 is surrounded by a side face constituting the storage portion 20e, and the front surface side shield layer 34 and the plurality of through holes 38c in the substrate 30, as indicated by a broken line arrow in FIG. 4, unnecessary emission of an unnecessary electromagnetic wave emitted from one main surface of the high-frequency amplifier 10 to a space outside the substrate 30 can be suppressed without shielding the high-frequency amplifier 10 with a metal cover.

Furthermore, since the depth of the storage portion 20e and the width of the storage portion 20e in a direction orthogonal to a straight line on which the input terminal 11 and the output terminal 12 of the high-frequency amplifier 10 are disposed on a plane including the straight line are each set to a value equal to or less than ½ of a wavelength λ of a frequency of a signal input to the high-frequency amplifier 10, an electromagnetic wave having a frequency equal to or less than the frequency of the signal input to the high-frequency amplifier 10 is hardly propagated between the input terminal 11 and the output terminal 12 of the high-frequency amplifier 10 via a space of the storage portion 20e, and oscillation between the input terminal 11 and the output terminal 12 can be suppressed.

As described above, the power amplification high-frequency circuit device according to the first embodiment has the storage portion 20e having a flat bottom surface in the upper wall 20a of the waveguide tube 20 in which the input waveguide tube 21 and the output waveguide tube 22 are disposed in such a way as to face each other with the short wall 23 interposed therebetween, and the high-frequency amplifier 10 is stored in the storage portion 20e with the bottom surface of the high-frequency amplifier 10 being in close contact with the bottom surface of the storage portion 20e. Therefore, heat generated by the high-frequency amplifier 10 can be dissipated from the upper wall 20a of the waveguide tube 20 to outside air.

In addition, in the power amplification high-frequency circuit device according to the first embodiment, the back surface side shield layer 37 on a lower surface of the substrate 30 is in close contact with an outer wall surface of the upper wall 20a of the waveguide tube 20, the front surface side shield layer 34 on an upper surface of the substrate 30 is disposed along a peripheral portion of the insulating substrate 31 and electrically connected by a plurality of through holes, and the substrate 30 seals a space formed by the storage portion 20e. Therefore, emission of an unnecessary electromagnetic wave emitted from the high-frequency amplifier 10 to a space outside the substrate 30 can be suppressed without shielding the high-frequency amplifier 10 with a metal cover.

Furthermore, in the power amplification high-frequency circuit device according to the first embodiment, the depth of the storage portion 20e and the width of the storage portion 20e in a direction orthogonal to a straight line on which the input terminal 11 and the output terminal 12 of the high-frequency amplifier 10 are disposed on a plane including the straight line are each set to a value equal to or less than ½ of a wavelength λ of a frequency of a signal input to the high-frequency amplifier 10. Therefore, oscillation between the input terminal 11 and the output terminal 12 due to an electromagnetic wave having a frequency of equal to or less than ½ of the wavelength λ of the frequency of the input signal can be suppressed.

### Second Embodiment

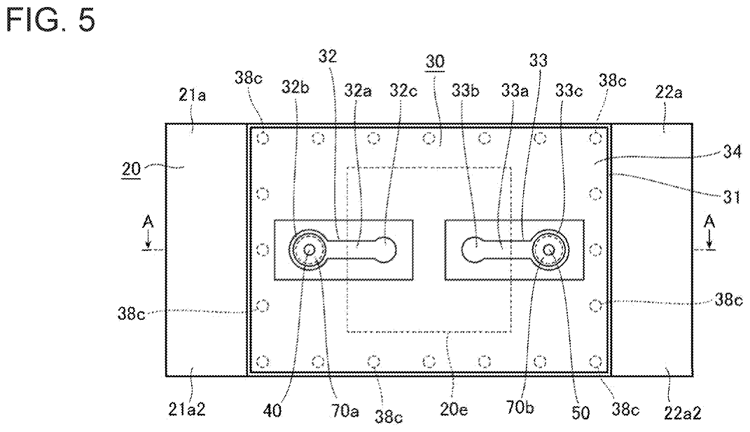

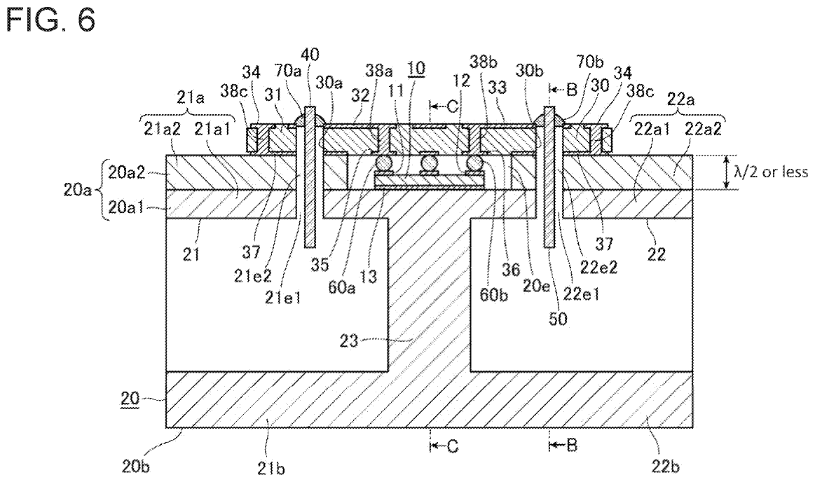

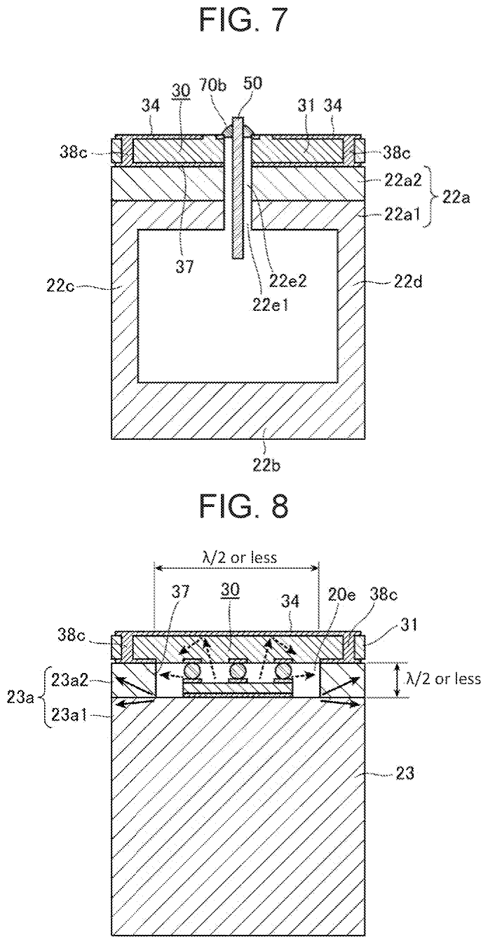

A power amplification high-frequency circuit device according to a second embodiment will be described with reference to FIGS. 5 to 8.

The power amplification high-frequency circuit device according to the second embodiment is different from the power amplification high-frequency circuit device according to the first embodiment in that an upper wall 20a of a waveguide tube 20 is divided into a lower portion upper wall 20a1 that is a first upper wall and an upper portion upper wall 20a2 that is a second upper wall, and is the same as the power amplification high-frequency circuit device according to the first embodiment in the other points.

Note that in FIGS. 5 to 8, the same reference numerals as those in FIGS. 1 to 4 denote the same or corresponding portions.

The total thickness of the lower portion upper wall 20a1 and the upper portion upper wall 20a2 in the power amplification high-frequency circuit device according to the second embodiment is the same as the thickness of the upper wall 20a of the waveguide tube 20 in the power amplification high-frequency circuit device according to the first embodiment.

An outer wall surface of the lower portion upper wall 20a1 is a flat surface, and is constituted integrally with a lower wall 20b and a pair of side walls 20c and 20d.

Note that dividing the upper wall 20a of the waveguide tube 20 into the lower portion upper wall 20a1 and the upper portion upper wall 20a2 means that upper walls 21a, 22a, and 23a of an input waveguide tube 21, an output waveguide tube 22, and a short wall 23 are divided into lower portion upper walls 21a1, 22a1, and 23a1 and upper portion upper walls 21a2, 22a2, and 23a2, respectively.

The upper portion upper wall 20a2 is a plate-shaped conductive plate having a thickness larger than the height of the high-frequency amplifier 10 and equal to or less than ½ of a wavelength λ of a signal frequency.

The upper portion upper wall 20a2 has an input pin insertion hole 21e2 which communicates with an input pin insertion hole 21e1 of the lower portion upper wall 20a1 and into which an input conversion pin 40 is inserted while maintaining an electrical insulating state from the upper portion upper wall 20a2.

The input pin insertion hole 21e2 in the upper portion upper wall 20a2 communicates with an input pin insertion hole 30a in a substrate 30.

The upper portion upper wall 20a2 has an output pin insertion hole 22e2 which communicates with an output pin insertion hole 22e1 of the lower portion upper wall 20a1 and into which an output conversion pin 50 is inserted while maintaining an electrical insulating state from the upper portion upper wall 20a2.

The output pin insertion hole 22e2 in the upper portion upper wall 20a2 communicates with an output pin insertion hole 30b in the substrate 30.

The upper portion upper wall 20a2 has a penetration hole for forming a storage portion 20e at a central portion thereof.

In the penetration hole in the upper portion upper wall 20a2, a plane, a lateral cross section, and a longitudinal cross section are quadrilateral.

The width of the penetration hole in the upper portion upper wall 20a2 in a longitudinal direction is longer than the width of the high-frequency amplifier 10 in the longitudinal direction and is equal to or less than ½ of a wavelength λ of a signal frequency.

The width of the penetration hole in the upper portion upper wall 20a2 in a lateral direction is longer than the width of the high-frequency amplifier 10 in the lateral direction and is preferably equal to or less than ½ of a wavelength λ of a signal frequency.

An inner wall surface of the upper portion upper wall 20a2 is closely fixed to an outer wall surface of the lower portion upper wall 20a1. As a result, the upper portion upper wall 20a2 and the lower portion upper wall 20a1 constitute the upper wall 20a of the waveguide tube 20.

The inner wall surface of the upper portion upper wall 20a2 is brought into close contact with the outer wall surface of the lower portion upper wall 20a1 by an adhesive, solder, a sintered material, or a sheet.

The penetration hole in the upper portion upper wall 20a2 is located in an upper portion of the short wall 23, an outer wall surface of the lower portion upper wall 21a1 of the input waveguide tube 21 on a second end side, and an outer wall surface of the lower portion upper wall 22a1 of the output waveguide tube 22 on a first end side.

A region surrounded by the penetration hole in the upper portion upper wall 20a2 and the outer wall surface of the lower portion upper wall 20a1 is the storage portion 20e, the outer wall surface of the lower portion upper wall 20a1 is a bottom surface of the storage portion 20e, and a side face of the penetration hole in the upper portion upper wall 20a2 is a side face of the storage portion 20e.

A back surface side shield layer 37 in the substrate 30 is closely fixed to the outer wall surface of the upper portion upper wall 20a2, and the substrate 30 is fixed to the upper portion upper wall 20a2.

Note that by using, for example, an elastic conductive elastic body such as conductive rubber as the upper portion upper wall 20a2, a stress due to intersection of the upper wall 20a in a thickness direction and a linear expansion difference from the lower portion upper wall 20a1 can be absorbed.

As described above, the power amplification high-frequency circuit device according to the second embodiment has similar effects to the power amplification high-frequency circuit device according to the first embodiment, and also facilitates formation of the storage portion.

### Third Embodiment

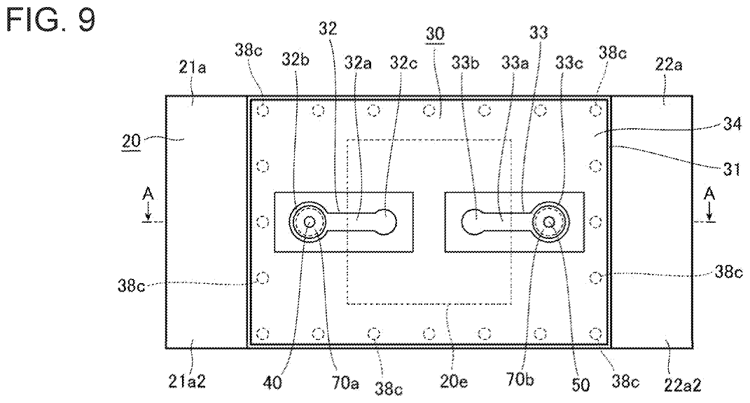

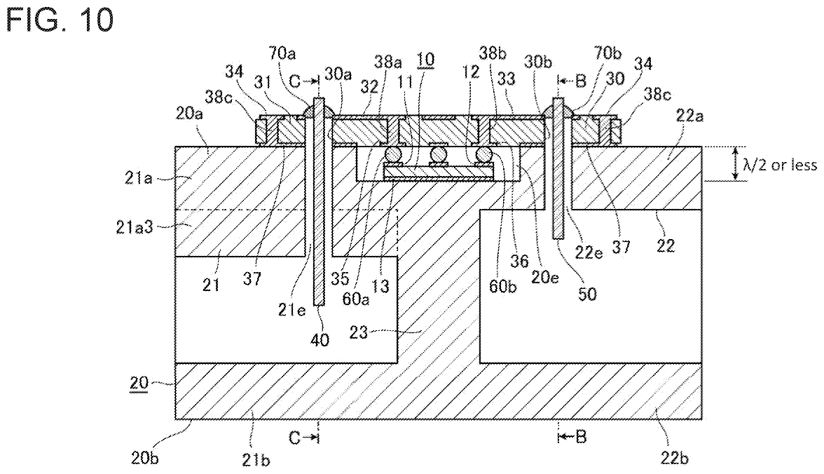

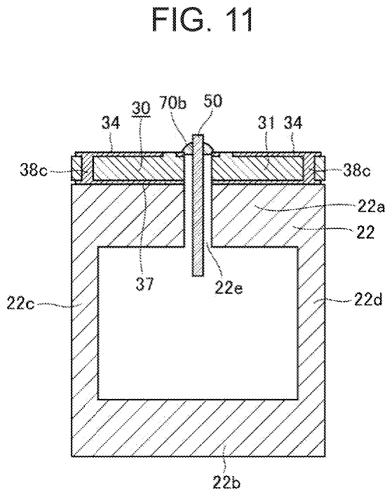

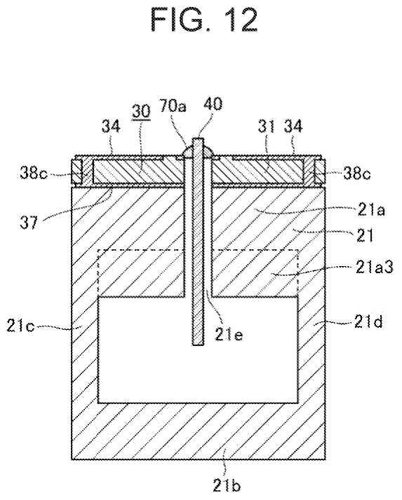

A power amplification high-frequency circuit device according to a third embodiment will be described with reference to FIGS. 9 to 12.

The power amplification high-frequency circuit device according to the third embodiment is different from the power amplification high-frequency circuit device according to the first embodiment in the shape of an upper wall of an input waveguide tube 21, and is the same as the power amplification high-frequency circuit device according to the first embodiment in the other points.

Note that in FIGS. 9 to 12, the same reference numerals as those in FIGS. 1 to 4 denote the same or corresponding portions.

The thickness of the upper wall of the input waveguide tube 21 is increased on a lower side with respect to the upper wall 21a of the input waveguide tube 21 in the power amplification high-frequency circuit device according to the first embodiment by the thickness of an additional upper wall 21a3.

That is, the upper wall of the input waveguide tube 21 includes the upper wall 21a and the additional upper wall 21a3 that are integrally configured.

Therefore, the wall thickness of the upper wall of the input waveguide tube 21 is larger than the wall thickness of an upper wall 22a of an output waveguide tube 22.

In addition, the inner dimension of the input waveguide tube 21, that is, the area of an inner cross section orthogonal to a tube axis of a waveguide is smaller than the inner dimension of the output waveguide tube 22, that is, the area of an inner cross section orthogonal to the tube axis of the waveguide. That is, a distance between an inner wall surface of the upper wall 21a of the input waveguide tube 21 and an inner wall surface of a lower wall 21b facing the upper wall 21a is shorter than a distance between an inner wall surface of the upper wall 22a of the output waveguide tube 22 and an inner wall surface of a lower wall 22b facing the upper wall 22a.

Note that a distance between a pair of side walls 21c and 21d of the input waveguide tube 21 is the same as a distance between a pair of side walls 22c and 22d of the output waveguide tube 22.

Even when the area of the inner cross section of the input waveguide tube 21 is smaller than the area of the inner cross section of the output waveguide tube 22, power of an electromagnetic wave incident from a first end opening of the input waveguide tube 21 is small. Therefore, large withstand power is not required, and there is no problem in withstand voltage performance of the input waveguide tube 21.

Note that since the thickness of the upper wall of the input waveguide tube 21 is increased by the thickness of the additional upper wall 21a3, the length of an input pin insertion hole 21e is also increased, and the length of an input conversion pin 40 is also increased by the thickness of the additional upper wall 21a3 than the length of an output conversion pin 50.

As described above, the power amplification high-frequency circuit device according to the third embodiment has similar effects to the power amplification high-frequency circuit device according to the first embodiment. In addition, the thickness of the upper wall of the input waveguide tube 21 is larger by the thickness of the additional upper wall 21a3. Therefore, the cross-sectional area of the waveguide tube 20 that can be used for dissipating heat generated by the high-frequency amplifier 10 increases, and the heat is more easily dissipated from the upper wall 20a of the waveguide tube 20 to outside air.

### Fourth Embodiment

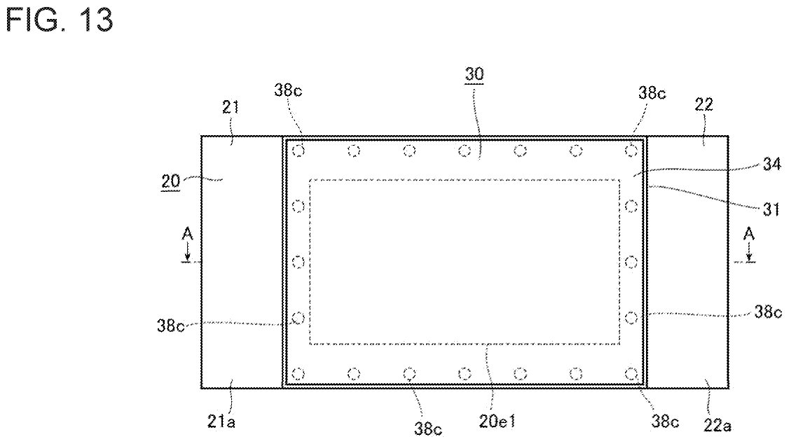

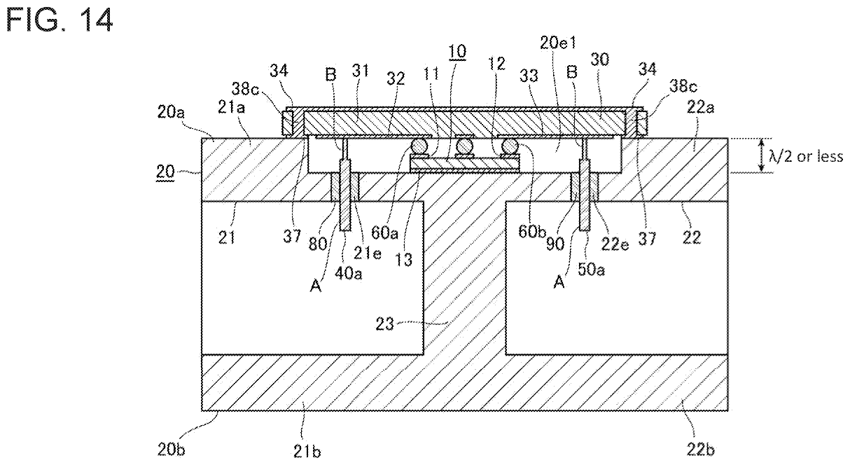

A power amplification high-frequency circuit device according to a fourth embodiment will be described with reference to FIGS. 13 and 14.

The power amplification high-frequency circuit device according to the fourth embodiment is different from the power amplification high-frequency circuit device according to the first embodiment in that the width of a storage portion 20e1 in a direction of a straight line on which an input terminal 11 and an output terminal 12 are disposed is set to a length including an input pin insertion hole 21e into which an input conversion pin 40a is inserted and an output pin insertion hole 22e into which an output conversion pin 50a is inserted, the input conversion pin 40a and the output conversion pin 50a are spring probes, and an input signal wiring layer 32 and an output signal wiring layer 33 in a substrate 30 are disposed on a back surface of an insulating substrate 31, and is the same as the power amplification high-frequency circuit device according to the first embodiment in the other points.

Note that in FIGS. 13 and 14, the same reference numerals as those in FIGS. 1 to 4 denote the same or corresponding portions.

The spring probe is a general spring probe having a fixed portion A and a movable portion B. The fixed portion A is a pipe, and the movable portion B is a pin. When the pin is pushed in a longitudinal direction of the probe, the pin is pushed back by a restoring force of a coil spring stored in the pipe.

The storage portion 20e1 is a recess formed of a space in which a bottom surface communicating with an upper portion of a short wall 23, an upper portion of the upper wall 21a of the input waveguide tube 21 on a second end side, and an upper portion of the upper wall 22a of the output waveguide tube 22 on a first end side is a flat surface, and a plane, a lateral cross section, and a longitudinal cross section are quadrilateral.

The position of the storage portion 20e1 in the upper wall 21a of the input waveguide tube 21 extends to a position including the input pin insertion hole 21e in the upper wall 21a.

The position of the storage portion 20e1 in the upper wall 22a of the output waveguide tube 22 extends to a position including the output pin insertion hole 22e in the upper wall 22a.

The substrate 30 includes the insulating substrate 31 having, on a front surface thereof, a front surface side shield layer 34 set to a ground potential, and having, on a back surface thereof, an input signal wiring layer 32, an output signal wiring layer 33, and a back surface side shield layer 37 set to a ground potential.

The input signal wiring layer 32 is disposed on a back surface of the insulating substrate 31 in such a way as to be disposed on a straight line parallel to a straight line on which the input terminal 11 and the output terminal 12 of the high-frequency amplifier 10 are disposed, and has a wiring layer that linearly connects an input end to an output end, in which the input end is a first end facing the input pin insertion hole 21e in the upper wall 21a of the input waveguide tube 21, and the output end is a second end facing the input terminal 11 of the high-frequency amplifier 10.

The output end of the input signal wiring layer 32 is electrically and mechanically connected to the input terminal 11 of the high-frequency amplifier 10 with a solder ball 60a.

The output signal wiring layer 33 is disposed on a back surface of the insulating substrate 31 in such a way as to be disposed on a straight line on which the input signal wiring layer 32 is disposed along a straight line on which the input terminal 11 and the output terminal 12 of the high-frequency amplifier 10 are disposed, and has a wiring layer that linearly connects an input end to an output end, in which the input end is a first end facing the output terminal 12 of the high-frequency amplifier 10, and the output end is a second end facing the output pin insertion hole 22e in the upper wall 22a of the output waveguide tube 22.

The input end of the output signal wiring layer 33 is electrically and mechanically connected to the output terminal 12 of the high-frequency amplifier 10 with a solder ball 60b.

As illustrated in FIG. 13, the front surface side shield layer 34 is a metal layer extending from a center of the insulating substrate 31 to a peripheral portion thereof.

The back surface side shield layer 37 is a metal layer surrounding the storage portion 20e1 and extending to a peripheral portion of the insulating substrate 31.

The back surface side shield layer 37 is in close contact with an outer wall surface of the upper wall 20a of the waveguide tube 20 excluding the storage portion 20e.

The back surface side shield layer 37 and the outer wall surface of the upper wall 20a of the waveguide tube 20 are brought into close contact with each other with an adhesive, solder, a sintered material, or a sheet.

The substrate 30 is closely fixed to the outer wall surface of the upper wall 20a of the waveguide tube 20. As a result, a space formed by the storage portion 20e1 is sealed by the substrate 30 and the upper wall 20a of the waveguide tube 20.

The front surface side shield layer 34 and the back surface side shield layer 37 are electrically connected to each other by a plurality of through holes 38c formed along four sides in a peripheral portion.

The fixed portion A of the input conversion pin 40 is inserted into the input pin insertion hole 21e in the upper wall 21a of the input waveguide tube 21, and the fixed portion is fixed to the upper wall 21a by an insulating adhesive 80.

The movable portion B of the input conversion pin 40 is located in a space formed by the storage portion 20e1.

Before the substrate 30 is attached to the upper wall 21a of the input waveguide tube 21, a distal end of the movable portion B of the input conversion pin 40 protrudes upward from an upper wall surface of the upper wall 21a of the input waveguide tube 21.

When the substrate 30 is attached to the upper wall 21a of the input waveguide tube 21, the movable portion B of the input conversion pin 40 is pushed down by the input end of the input signal wiring layer 32 in the substrate 30, and a distal end of the movable portion B is brought into close contact with the input end of the input signal wiring layer 32 by an elastic force and electrically connected to the input end.

The fixed portion A of the output conversion pin 50 is inserted into the output pin insertion hole 22e in the upper wall 22a of the output waveguide tube 22, and the fixed portion is fixed to the upper wall 22a by an insulating adhesive 90.

The movable portion B of the output conversion pin 50 is located in a space formed by the storage portion 20e1.

Before the substrate 30 is attached to the upper wall 22a of the output waveguide tube 22, a distal end of the movable portion B of the output conversion pin 50 protrudes upward from an upper wall surface of the upper wall 22a of the output waveguide tube 22.

When the substrate 30 is attached to the upper wall 22a of the output waveguide tube 22, the movable portion B of the output conversion pin 50 is pushed down by the output end of the output signal wiring layer 33 in the substrate 30, and a distal end of the movable portion B is brought into close contact with the output end of the output signal wiring layer 33 by an elastic force and electrically connected to the output end.

Next, an operation of the power amplification high-frequency circuit device according to the fourth embodiment configured as described above will be described.

An electromagnetic wave incident on a first end opening of the input waveguide tube 21 is converted from an electromagnetic field mode of the waveguide tube 20 to a TEM mode through the input conversion pin 40a, and is transmitted as a high-frequency signal from the movable portion B of the input conversion pin 40a to the input terminal 11 of the high-frequency amplifier 10 via the input signal wiring layer 32 in the substrate 30 and the solder ball 60a.

The signal input to the input terminal 11 of the high-frequency amplifier 10 is amplified by the high-frequency amplifier 10, and is output as an amplified high-frequency signal from the output terminal 12 of the high-frequency amplifier 10.

The high-frequency signal output from the output terminal 12 of the high-frequency amplifier 10 is transmitted to the output conversion pin 50a via the solder ball 60b and the output signal wiring layer 33 in the substrate 30.

The high-frequency signal transmitted to the output conversion pin 50a is converted from the TEM mode to a mode of the waveguide tube 20 by the output conversion pin 50a, and is output from a second end opening of the output waveguide tube 22.

As described above, the power amplification high-frequency circuit device according to the fourth embodiment has similar effects to the power amplification high-frequency circuit device according to the first embodiment.

### Fifth Embodiment

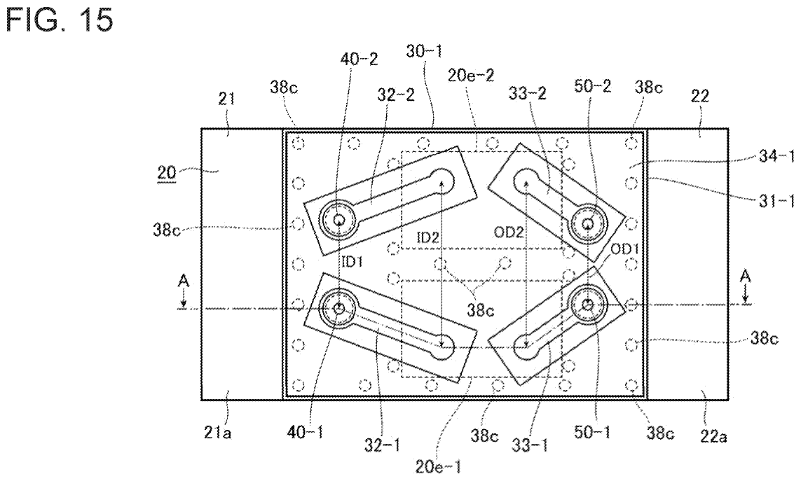

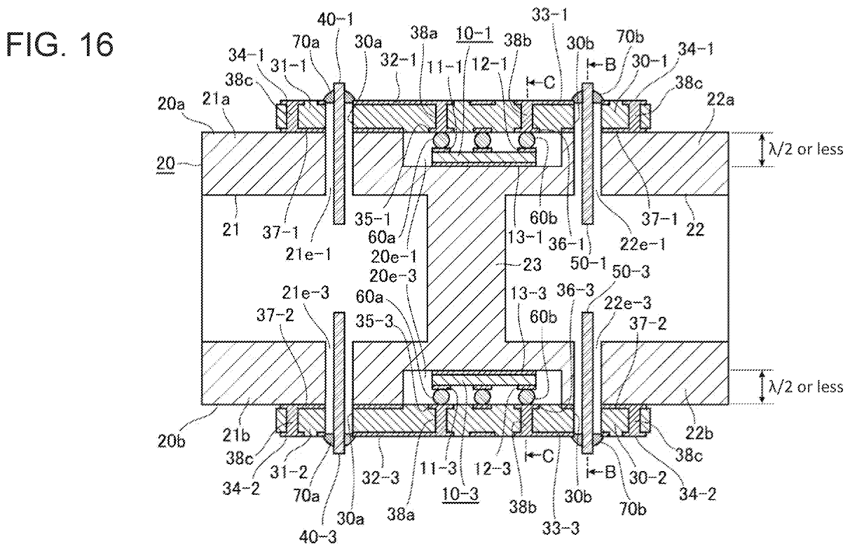

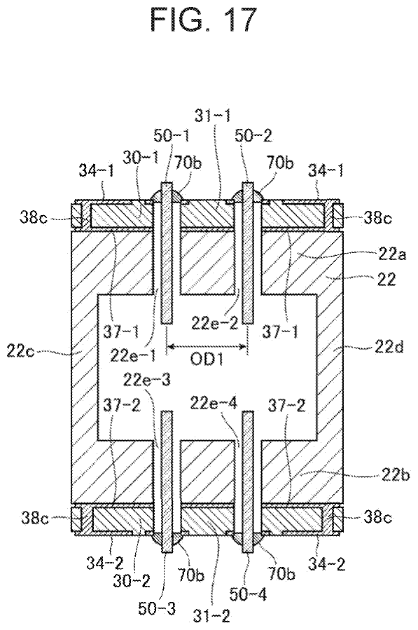

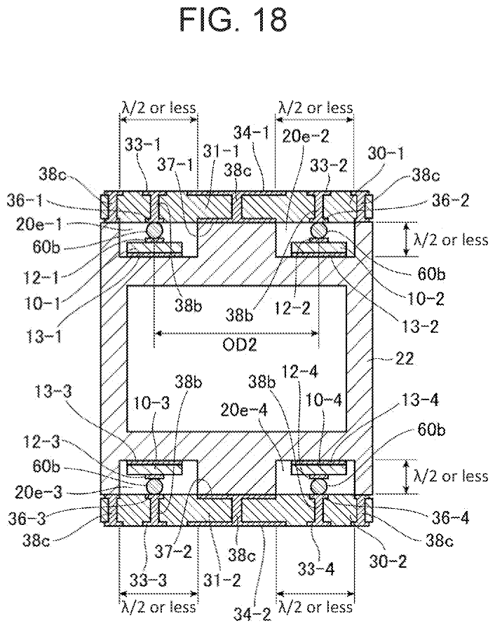

A power amplification high-frequency circuit device according to a fifth embodiment will be described with reference to FIGS. 15 to 18.

The power amplification high-frequency circuit device according to the first embodiment includes one high-frequency amplifier 10 for the waveguide tube 20.

Meanwhile, the power amplification high-frequency circuit device according to the fifth embodiment is different from the power amplification high-frequency circuit device according to the first embodiment in that four high-frequency amplifiers 10-1 to 10-4 are disposed for a waveguide tube 20, and in components related to the four high-frequency amplifiers 10-1 to 10-4, and is the same as the power amplification high-frequency circuit device according to the first embodiment in the other points.

Note that in FIGS. 15 to 18, the same reference numerals as those in FIGS. 1 to 4 denote the same or corresponding portions.

The power amplification high-frequency circuit device according to the fifth embodiment includes the first high-frequency amplifier 10-1 to the fourth high-frequency amplifier 10-4, the waveguide tube 20, a first substrate 30-1 and a second substrate 30-2, a first input conversion pin 40-1 to a fourth input conversion pin 40-4, and a first output conversion pin 50-1 to a fourth output conversion pin 50-4.

In the power amplification high-frequency circuit device according to the fifth embodiment, an electromagnetic wave incident on a first end opening of an input waveguide tube 21 in the waveguide tube 20 is converted into a TEM mode and divided into four signals via the first input conversion pin 40-1 to the fourth input conversion pin 40-4, the divided signals are amplified by the first high-frequency amplifier 10-1 to the fourth high-frequency amplifier 10-4, respectively, the amplified signals are converted from the TEM mode to a TE01 mode via the first output conversion pin 50-1 to the fourth output conversion pins 50-4, respectively, the four converted signals are combined, and the combined signal is output from a second end opening of an output waveguide tube 22.

Each of the first high-frequency amplifier 10-1 to the fourth high-frequency amplifier 10-4 is substantially the same amplifier as the high-frequency amplifier 10 in the power amplification high-frequency circuit device according to the first embodiment.

Each of the first input conversion pin 40-1 to the fourth input conversion pin 40-4 is substantially the same pin as the input conversion pin 40 in the power amplification high-frequency circuit device according to the first embodiment.

Each of the first output conversion pin 50-1 to the fourth output conversion pin 50-4 is substantially the same pin as the output conversion pin 50 in the power amplification high-frequency circuit device according to the first embodiment.

The waveguide tube 20 includes the input waveguide tube 21, the output waveguide tube 22, and a short wall 23, and the input waveguide tube 21 and the output waveguide tube 22 are disposed in such a way as to face each other with the short wall 23 interposed therebetween and are integrally constituted.

The waveguide tube 20 is made of metal and set to a ground potential.

An upper wall 21a of the input waveguide tube 21 has a first input pin insertion hole 21e-1 into which the first input conversion pin 40-1 is inserted while maintaining an electrical insulating state from the upper wall 21a, and a second input pin insertion hole 21e-2 into which the second input conversion pin 40-2 is inserted while maintaining an electrical insulating state from the upper wall 21a.

The first input pin insertion hole 21e-1 and the second input pin insertion hole 21e-2 are formed with an interval ID1 on a straight line in a direction orthogonal to a straight line on which an input terminal 11 and an output terminal 12 of the high-frequency amplifier 10 are disposed, that is, a straight line parallel to a tube axis of the waveguide tube 20 on a plane including the straight line.

A lower wall 21b of the input waveguide tube 21 has a third input pin insertion hole 21e-3 into which the third input conversion pin 40-3 is inserted while maintaining an electrical insulating state from the lower wall 21b, and a fourth input pin insertion hole 21e-4 into which the fourth input conversion pin 40-4 is inserted while maintaining an electrical insulating state from the lower wall 21b.

The third input pin insertion hole 21e-3 is at a position facing the first input pin insertion hole 21e-1, the fourth input pin insertion hole 21e-4 is at a position facing the second input pin insertion hole 21e-2, and the third input pin insertion hole 21e-3 and the fourth input pin insertion hole 21e-4 are formed with an interval ID1 on a straight line in a direction orthogonal to a straight line parallel to the tube axis of the waveguide tube 20 on a plane including the straight line.

A first end of each of the first input conversion pin 40-1 and the second input conversion pin 40-2 protrudes inward of the upper wall 21a, and a second end thereof protrudes outward of the upper wall 21a.

A first end of each of the third input conversion pin 40-3 and the fourth input conversion pin 40-4 protrudes inward of the lower wall 21b, and a second end thereof protrudes outward of the lower wall 21b.

An upper wall 22a of the output waveguide tube 22 has a first output pin insertion hole 22e-1 into which the first output conversion pin 50-1 is inserted while maintaining an electrical insulating state from the upper wall 22a, and a second output pin insertion hole 22e-2 into which the second output conversion pin 50-2 is inserted while maintaining an electrical insulating state from the upper wall 22a.

The first output pin insertion hole 22e-1 is located on a straight line parallel to the tube axis of the waveguide tube 20 together with the first input pin insertion hole 21e-1.

The second output pin insertion hole 22e-2 is located on a straight line parallel to the tube axis of the waveguide tube 20 together with the second input pin insertion hole 21e-2.

The first output pin insertion hole 22e-1 and the second output pin insertion hole 22e-2 are formed with an interval OD1 on a straight line in a direction orthogonal to a straight line parallel to the tube axis of the waveguide tube 20 on a plane including the straight line.

A lower wall 22b of the output waveguide tube 22 has a third output pin insertion hole 22e-3 into which the third output conversion pin 50-3 is inserted while maintaining an electrical insulating state from the lower wall 22b, and a fourth output pin insertion hole 22e-4 into which the fourth input conversion pin 50-4 is inserted while maintaining an electrical insulating state from the lower wall 22b.

The third output pin insertion hole 22e-3 is located at a position facing the first output pin insertion hole 22e-1, and is located on a straight line parallel to the tube axis of the waveguide tube 20 together with the third input pin insertion hole 21e-3.

The fourth output pin insertion hole 22e-4 is located at a position facing the second output pin insertion hole 22e-2, and is located on a straight line parallel to the tube axis of the waveguide tube 20 together with the fourth input pin insertion hole 21e-4.

The third output pin insertion hole 22e-3 and the fourth output pin insertion hole 22e-4 are formed with an interval OD1 on a straight line in a direction orthogonal to a straight line parallel to the tube axis of the waveguide tube 20 on a plane including the straight line.

A first end of each of the first output conversion pin 50-1 and the second output conversion pin 50-2 protrudes inward of the upper wall 22a, and a second end thereof protrudes outward of the upper wall 22a.

A first end of each of the third input conversion pin 40-3 and the fourth input conversion pin 40-4 protrudes inward of the lower wall 22b, and a second end thereof protrudes outward of the lower wall 22b.

The upper wall 20a of the waveguide tube 20 has a first storage portion 20e-1 and a second storage portion 20e-2 in parallel in a direction orthogonal to a straight line parallel to the tube axis of the waveguide tube 20 on a plane including the straight line at a central portion thereof.

Each of the first storage portion 20e-1 and the second storage portion 20e-2 has a depth from an outer wall surface of the upper wall 20a deeper than the height of each of the first high-frequency amplifier 10-1 and the second high-frequency amplifier 10-2, has a flat bottom surface, and has the same shape as the storage portion 20e in the power amplification high-frequency circuit device according to the first embodiment.

The first storage portion 20e-1 is located between the first input conversion pin 40-1 and the first output conversion pin 50-1, and a center thereof is located on the first output conversion pin 50-1 side.

The second storage portion 20e-2 is located between the second input conversion pin 40-2 and the second output conversion pin 50-2, and a center thereof is located on the second output conversion pin 50-2 side.

The first high-frequency amplifier 10-1 is stored in the first storage portion 20e-1, and an input and output common terminal 13 disposed on the entire other main surface of the first high-frequency amplifier 10-1 is closely fixed to a bottom surface of the first storage portion 20e-1.

The input terminal 11 and the output terminal 12 in the first high-frequency amplifier 10-1 stored in the first storage portion 20e-1 are located on a straight line parallel to the tube axis of the waveguide tube 20.

The second high-frequency amplifier 10-2 is stored in the second storage portion 20e-2, and an input and output common terminal 13 disposed on the entire other main surface of the second high-frequency amplifier 10-2 is closely fixed to a bottom surface of the second storage portion 20e-2.

The input terminal 11 and the output terminal 12 in the second high-frequency amplifier 10-2 stored in the second storage portion 20e-2 are located on a straight line parallel to the tube axis of the waveguide tube 20.

An interval ID2 between the input terminal 11 in the first high-frequency amplifier 10-1 stored in the first storage portion 20e-1 and the input terminal 11 in the second high-frequency amplifier 10-2 stored in the second storage portion 20e-2 is wider than the interval ID1 between the first input pin insertion hole 21e-1 and the second input pin insertion hole 21e-2.

That is, the interval ID1 between the first input conversion pin 40-1 inserted into the first input pin insertion hole 21e-1 and the second input conversion pin 40-2 inserted into the second input pin insertion hole 21e-2 is narrower than the interval ID2 between the input terminal 11 in the first high-frequency amplifier 10-1 and the input terminal 11 in the second high-frequency amplifier 10-2.

An interval OD2 between the output terminal 12 in the first high-frequency amplifier 10-1 stored in the first storage portion 20e-1 and the output terminal 12 in the second high-frequency amplifier 10-2 stored in the second storage portion 20e-2 is wider than the interval OD1 between the first output pin insertion hole 22e-1 and the second output pin insertion hole 22e-2.

That is, the interval OD1 between the first output conversion pin 50-1 inserted into the first output pin insertion hole 22e-1 and the second output conversion pin 50-2 inserted into the second output pin insertion hole 22e-2 is narrower than the interval OD2 between the output terminal 12 in the first high-frequency amplifier 10-1 and the output terminal 12 in the second high-frequency amplifier 10-2.

The lower wall 20b of the waveguide tube 20 has a third storage portion 20e-3 and a fourth storage portion 20e-4 in parallel in a direction orthogonal to a straight line parallel to the tube axis of the waveguide tube 20 on a plane including the straight line at a central portion thereof.

Each of the third storage portion 20e-3 and the fourth storage portion 20e-4 has a depth from an outer wall surface of the lower wall 20b deeper than the height of each of the third high-frequency amplifier 10-3 and the fourth high-frequency amplifier 10-4, has a flat bottom surface, and has the same shape as the storage portion 20e in the power amplification high-frequency circuit device according to the first embodiment.

The third storage portion 20e-3 is located between the third input conversion pin 40-3 and the third output conversion pin 50-3, and a center thereof is located on the third output conversion pin 50-3 side.

The third storage portion 20e-3 is at a position facing the first storage portion 20e-1.

The fourth storage portion 20e-4 is located between the fourth input conversion pin 40-4 and the fourth output conversion pin 50-4, and a center thereof is located on the fourth output conversion pin 50-4 side.

The fourth storage portion 20e-4 is at a position facing the second storage portion 20e-2.

The third high-frequency amplifier 10-3 is stored in the third storage portion 20e-3, and an input and output common terminal 13 disposed on the entire other main surface of the third high-frequency amplifier 10-3 is closely fixed to a bottom surface of the third storage portion 20e-3.

The input terminal 11 and the output terminal 12 in the third high-frequency amplifier 10-3 stored in the third storage portion 20e-3 are located on a straight line parallel to the tube axis of the waveguide tube 20.

The fourth high-frequency amplifier 10-4 is stored in the fourth storage portion 20e-4, and an input and output common terminal 13 disposed on the entire other main surface of the fourth high-frequency amplifier 10-4 is closely fixed to a bottom surface of the fourth storage portion 20e-4.

The input terminal 11 and the output terminal 12 in the fourth high-frequency amplifier 10-4 stored in the fourth storage portion 20e-4 are located on a straight line parallel to the tube axis of the waveguide tube 20.

An interval ID2 between the input terminal 11 in the third high-frequency amplifier 10-3 stored in the third storage portion 20e-3 and the input terminal 11 in the fourth high-frequency amplifier 10-4 stored in the fourth storage portion 20e-4 is wider than the interval ID1 between the third input pin insertion hole 21e-3 and the fourth input pin insertion hole 21e-4.

That is, the interval ID1 between the third input conversion pin 40-3 inserted into the third input pin insertion hole 21e-3 and the fourth input conversion pin 40-4 inserted into the fourth input pin insertion hole 21e-4 is narrower than the interval ID2 between the input terminal 11 in the third high-frequency amplifier 10-3 and the input terminal 11 in the fourth high-frequency amplifier 10-4.

An interval OD2 between the output terminal 12 in the third high-frequency amplifier 10-3 stored in the third storage portion 20e-3 and the output terminal 12 in the fourth high-frequency amplifier 10-4 stored in the fourth storage portion 20e-4 is wider than the interval OD1 between the third output pin insertion hole 22e-3 and the fourth output pin insertion hole 22e-4.

That is, the interval OD1 between the third output conversion pin 50-3 inserted into the third output pin insertion hole 22e-3 and the fourth output conversion pin 50-4 inserted into the fourth output pin insertion hole 22e-4 is narrower than the interval OD2 between the output terminal 12 in the third high-frequency amplifier 10-3 and the output terminal 12 in the fourth high-frequency amplifier 10-4.

The first substrate 30-1 includes a first insulating substrate 31-1 having, on a front surface thereof, a first input signal wiring layer 32-1, a second input signal wiring layer 32-2, a first output signal wiring layer 33-1, a second output signal wiring layer 33-2, and a first front surface side shield layer 34-1 set to a ground potential, and having, on a back surface thereof, an input signal land 35, an output signal land 36, and a first back surface side shield layer 37-1 set to a ground potential.

The first substrate 30-1 has a first input pin insertion hole 30a-1 communicating with the first input pin insertion hole 21e-1 formed in the upper wall 21a of the input waveguide tube 21, a second input pin insertion hole 30a-2 communicating with the second input pin insertion hole 21e-2 formed in the upper wall 21a, a first output pin insertion hole 30b-1 communicating with the first output pin insertion hole 22e-1 formed in the upper wall 22a of the output waveguide tube 22, and a second output pin insertion hole 30b-2 communicating with the second output pin insertion hole 22e-2 formed in the upper wall 22a.

The first input signal wiring layer 32-1 is disposed on a straight line parallel to a straight line connecting the input terminal 11 of the first high-frequency amplifier 10-1 to the first input pin insertion hole 30a-1, has a land 32b surrounding an upper end opening of the first input pin insertion hole 30a-1 at a first end, has a land 32c at a position facing the input terminal 11 of the first high-frequency amplifier 10-1 at a second end, and has a wiring layer 32a linearly connecting the land 32b to the land 32c.

The second input signal wiring layer 32-2 is disposed on a straight line parallel to a straight line connecting the input terminal 11 of the second high-frequency amplifier 10-2 to the second input pin insertion hole 30a-2, has a land 32b surrounding an upper end opening of the second input pin insertion hole 30a-2 at a first end, has a land 32c at a position facing the input terminal 11 of the second high-frequency amplifier 10-2 at a second end, and has a wiring layer 32a linearly connecting the land 32b to the land 32c.

The first output signal wiring layer 33-1 is disposed on a straight line parallel to a straight line connecting the output terminal 12 of the first high-frequency amplifier 10-1 to the first output pin insertion hole 30b-1, has a land 33b surrounding an upper end opening of the first output pin insertion hole 30b-1 at a first end, has a land 33c at a position facing the output terminal 12 of the first high-frequency amplifier 10-1 at a second end, and has a wiring layer 33a linearly connecting the land 33b to the land 33c.

The length of the first output signal wiring layer 33-1 is preferably a minimum wiring length required for matching between the output terminal 12 of the first high-frequency amplifier 10-1 and the output waveguide tube 22, that is, a matching circuit.

As described above, by setting the length of the first output signal wiring layer 33-1 to a minimum wiring length required for a matching circuit, a loss in the first output signal wiring layer 33-1 can be reduced.

The second output signal wiring layer 33-2 is disposed on a straight line parallel to a straight line connecting the output terminal 12 of the second high-frequency amplifier 10-2 to the second output pin insertion hole 30b-2, has a land 33b surrounding an upper end opening of the second output pin insertion hole 30b-2 at a first end, has a land 33c at a position facing the output terminal 12 of the second high-frequency amplifier 10-2 at a second end, and has a wiring layer 33a linearly connecting the land 33b to the land 33c.

The length of the second output signal wiring layer 33-2 is preferably a minimum wiring length required for matching between the output terminal 12 of the second high-frequency amplifier 10-2 and the output waveguide tube 22, that is, a matching circuit.

As described above, by setting the length of the second output signal wiring layer 33-2 to a minimum wiring length required for a matching circuit, a loss in the second output signal wiring layer 33-2 can be reduced.

The first front surface side shield layer 34-1 is a metal layer that is electrically insulated from the first input signal wiring layer 32-1, the second input signal wiring layer 32-2, the first output signal wiring layer 33-1, and the second output signal wiring layer 33-2, surrounds the first input signal wiring layer 32-1, the second input signal wiring layer 32-2, the first output signal wiring layer 33-1, and the second output signal wiring layer 33-2, and extends to a peripheral portion of the first insulating substrate 31-1.

The first back surface side shield layer 37-1 is a metal layer surrounding the first storage portion 20e-1 and the second storage portion 20e-2 and extending to a peripheral portion of the first insulating substrate 31-1.

The first back surface side shield layer 37-1 is in close contact with an outer wall surface of the upper wall 20a of the waveguide tube 20 excluding the first storage portion 20e-1 and the second storage portion 20e-2.

The first substrate 30-1 is closely fixed to the outer wall surface of the upper wall 20a of the waveguide tube 20. As a result, a space formed by each of the first storage portion 20e-1 and the second storage portion 20e-2 is sealed by the first substrate 30-1 and the upper wall 20a of the waveguide tube 20.

The first front surface side shield layer 34-1 and the first back surface side shield layer 37-1 are electrically connected to a peripheral portion of the first insulating substrate 31-1 and a storage portion peripheral portion of the first insulating substrate 31-1 surrounding the first storage portion 20e-1 and the second storage portion 20e-2 by a plurality of through holes 38c formed in such a way as to surround a periphery.

The second substrate 30-2 includes a second insulating substrate 31-2 having, on a front surface thereof, a third input signal wiring layer 32-3, a fourth input signal wiring layer 32-4, a third output signal wiring layer 33-3, a fourth output signal wiring layer 33-4, and a second front surface side shield layer 34-2 set to a ground potential, and having, on a back surface thereof, an input signal land 35, an output signal land 36, and a second back surface side shield layer 37-2 set to a ground potential.

The second substrate 30-2 has a third input pin insertion hole 30a-3 communicating with the third input pin insertion hole 21e-3 formed in the lower wall 21b of the input waveguide tube 21, a fourth input pin insertion hole 30a-4 communicating with the fourth input pin insertion hole 21e-4 formed in the lower wall 21b, a third output pin insertion hole 30b-3 communicating with the third output pin insertion hole 22e-3 formed in the lower wall 21b of the output waveguide tube 22, and a fourth output pin insertion hole 30b-4 communicating with the fourth output pin insertion hole 22e-4 formed in the lower wall 21b.

The third input signal wiring layer 32-3 is disposed on a straight line parallel to a straight line connecting the input terminal 11 of the third high-frequency amplifier 10-3 to the third input pin insertion hole 30a-3, has a land 32b surrounding an upper end opening of the third input pin insertion hole 30a-3 at a first end, has a land 32c at a position facing the input terminal 11 of the third high-frequency amplifier 10-3 at a second end, and has a wiring layer 32a linearly connecting the land 32b to the land 32c.

The fourth input signal wiring layer 32-4 is disposed on a straight line parallel to a straight line connecting the input terminal 11 of the fourth high-frequency amplifier 10-4 to the fourth input pin insertion hole 30a-4, has a land 32b surrounding an upper end opening of the fourth input pin insertion hole 30a-4 at a first end, has a land 32c at a position facing the input terminal 11 of the fourth high-frequency amplifier 10-4 at a second end, and has a wiring layer 32a linearly connecting the land 32b to the land 32c.

The third output signal wiring layer 33-3 is disposed on a straight line parallel to a straight line connecting the output terminal 12 of the third high-frequency amplifier 10-3 to the third output pin insertion hole 30b-3, has a land 33b surrounding an upper end opening of the third output pin insertion hole 30b-3 at a first end, has a land 33c at a position facing the output terminal 12 of the third high-frequency amplifier 10-3 at a second end, and has a wiring layer 33a linearly connecting the land 33b to the land 33c.

The length of the third output signal wiring layer 33-3 is preferably a minimum wiring length required for matching between the output terminal 12 of the third high-frequency amplifier 10-3 and the output waveguide tube 22, that is, a matching circuit.

As described above, by setting the length of the third output signal wiring layer 33-3 to a minimum wiring length required for a matching circuit, a loss in the third output signal wiring layer 33-3 can be reduced.

The fourth output signal wiring layer 33-4 is disposed on a straight line parallel to a straight line connecting the output terminal 12 of the fourth high-frequency amplifier 10-4 to the fourth output pin insertion hole 30b-4, has a land 33b surrounding an upper end opening of the fourth output pin insertion hole 30b-4 at a first end, has a land 33c at a position facing the output terminal 12 of the fourth high-frequency amplifier 10-4 at a second end, and has a wiring layer 33a linearly connecting the land 33b to the land 33c.

The length of the fourth output signal wiring layer 33-4 is preferably a minimum wiring length required for matching between the output terminal 12 of the fourth high-frequency amplifier 10-4 and the output waveguide tube 22, that is, a matching circuit.

As described above, by setting the length of the fourth output signal wiring layer 33-4 to a minimum wiring length required for a matching circuit, a loss in the fourth output signal wiring layer 33-4 can be reduced.

The second front surface side shield layer 34-2 is a metal layer that is electrically insulated from the third input signal wiring layer 32-3, the fourth input signal wiring layer 32-4, the third output signal wiring layer 33-3, and the fourth output signal wiring layer 33-4, surrounds the third input signal wiring layer 32-3, the fourth input signal wiring layer 32-4, the third output signal wiring layer 33-3 and the fourth output signal wiring layer 33-4, and extends to a peripheral portion of the second insulating substrate 31-2.

The second back surface side shield layer 37-2 is a metal layer surrounding the third storage portion 20e-3 and the fourth storage portion 20e-4 and extending to a peripheral portion of the second insulating substrate 31-2.

The second back surface side shield layer 37-2 is in close contact with an outer wall surface of the upper wall 20a of the waveguide tube 20 excluding the third storage portion 20e-3 and the fourth storage portion 20e-4.

The second substrate 30-2 is closely fixed to the outer wall surface of the upper wall 20a of the waveguide tube 20. As a result, a space formed by each of the third storage portion 20e-3 and the fourth storage portion 20e-4 is sealed by the second substrate 30-2 and the upper wall 20a of the waveguide tube 20.

The second front surface side shield layer 34-2 and the second back surface side shield layer 37-2 are electrically connected to a peripheral portion of the second insulating substrate 31-2 and a storage portion peripheral portion of the second insulating substrate 31-2 surrounding the third storage portion 20e-3 and the fourth storage portion 20e-4 by a plurality of through holes 38c formed in such a way as to surround a periphery.

The first input conversion pin 40-1 is inserted into the first input pin insertion hole 30a-1 and the first input pin insertion hole 21e-1 formed in the upper wall 21a of the input waveguide tube 21 from an upper end opening of the first input pin insertion hole 30a-1 of the first substrate 30-1 while being electrically insulated from the first substrate 30-1 and the upper wall 21a of the input waveguide tube 21, and a first end of the first input conversion pin 40-1 protrudes into the input waveguide tube 21.

A second end portion of the first input conversion pin 40-1 is electrically and mechanically connected to the land 32b of the first input signal wiring layer 32-1 with a solder 70a.

The second input conversion pin 40-2 is inserted into the second input pin insertion hole 30a-2 and the second input pin insertion hole 21e-2 formed in the upper wall 21a of the input waveguide tube 21 from an upper end opening of the second input pin insertion hole 30a-2 of the first substrate 30-1 while being electrically insulated from the first substrate 30-1 and the upper wall 21a of the input waveguide tube 21, and a first end of the second input conversion pin 40-2 protrudes into the input waveguide tube 21.

A second end portion of the second input conversion pin 40-2 is electrically and mechanically connected to the land 32b of the second input signal wiring layer 32-2 with a solder 70a.

The first output conversion pin 50-1 is inserted into the first output pin insertion hole 30b-1 and the first output pin insertion hole 22e-1 formed in the upper wall 22a of the output waveguide tube 22 from an upper end opening of the first output pin insertion hole 30b-1 of the first substrate 30-1 while being electrically insulated from the first substrate 30-1 and the upper wall 22a of the output waveguide tube 22, and a first end of the first output conversion pin 50-1 protrudes into the output waveguide tube 22.

A second end portion of the first output conversion pin 50-1 is electrically and mechanically connected to the land 33b of the first output signal wiring layer 33-1 with a solder 70b.

The second output conversion pin 50-2 is inserted into the second output pin insertion hole 30b-2 and the second output pin insertion hole 22e-2 formed in the upper wall 22a of the output waveguide tube 22 from an upper end opening of the second output pin insertion hole 30b-2 of the first substrate 30-1 while being electrically insulated from the first substrate 30-1 and the upper wall 22a of the output waveguide tube 22, and a first end of the second output conversion pin 50-2 protrudes into the output waveguide tube 22.

A second end portion of the second output conversion pin 50-2 is electrically and mechanically connected to the land 33b of the second output signal wiring layer 33-2 with a solder 70b.

The third input conversion pin 40-3 is inserted into the third input pin insertion hole 30a-3 and the third input pin insertion hole 21e-3 formed in the lower wall 21b of the input waveguide tube 21 from an upper end opening of the third input pin insertion hole 30a-3 of the second substrate 30-2 while being electrically insulated from the second substrate 30-2 and the lower wall 21b of the input waveguide tube 21, and a first end of the third input conversion pin 40-3 protrudes into the input waveguide tube 21.

A second end portion of the third input conversion pin 40-3 is electrically and mechanically connected to the land 32b of the third input signal wiring layer 32-3 with a solder 70a.

A first end of the third input conversion pin 40-3 faces a first end of the first input conversion pin 40-1.

The fourth input conversion pin 40-4 is inserted into the fourth input pin insertion hole 30a-4 and the fourth input pin insertion hole 21e-4 formed in the lower wall 21b of the input waveguide tube 21 from an upper end opening of the fourth input pin insertion hole 30a-4 of the second substrate 30-2 while being electrically insulated from the second substrate 30-2 and the lower wall 21b of the input waveguide tube 21, and a first end of the fourth input conversion pin 40-4 protrudes into the input waveguide tube 21.

A second end portion of the fourth input conversion pin 40-4 is electrically and mechanically connected to the land 32b of the fourth input signal wiring layer 32-4 with a solder 70a.

A first end of the fourth input conversion pin 40-4 faces a first end of the second input conversion pin 40-2.

The third output conversion pin 50-3 is inserted into the third output pin insertion hole 30b-3 and the third output pin insertion hole 22e-3 formed in the lower wall 22b of the output waveguide tube 22 from an upper end opening of the third output pin insertion hole 30b-3 of the second substrate 30-2 while being electrically insulated from the second substrate 30-2 and the lower wall 22b of the output waveguide tube 22, and a first end of the third output conversion pin 50-3 protrudes into the output waveguide tube 22.

A second end portion of the third output conversion pin 50-3 is electrically and mechanically connected to the land 33b of the third output signal wiring layer 33-3 with a solder 70b.

A first end of the third output conversion pin 50-3 faces a first end of the first output conversion pin 50-1.

The fourth output conversion pin 50-4 is inserted into the fourth output pin insertion hole 30b-4 and the fourth output pin insertion hole 22e-4 formed in the lower wall 22b of the output waveguide tube 22 from an upper end opening of the fourth output pin insertion hole 30b-4 of the second substrate 30-2 while being electrically insulated from the second substrate 30-2 and the lower wall 22b of the output waveguide tube 22, and a first end of the fourth output conversion pin 50-4 protrudes into the output waveguide tube 22.

A second end portion of the fourth output conversion pin 50-4 is electrically and mechanically connected to the land 33b of the fourth output signal wiring layer 33-4 with a solder 70b.

A first end of the fourth output conversion pin 50-4 faces a first end of the second output conversion pin 50-2.

The power amplification high-frequency circuit device according to the fifth embodiment configured as described above has a vertically symmetrical structure with respect to a plane passing through the tube axis of the waveguide tube 20 and passing through centers of the pair of side walls 20c and 20d.

Next, an operation of the power amplification high-frequency circuit device according to the fifth embodiment configured as described above will be described.

An electromagnetic wave that is incident on a first end opening of the input waveguide tube 21 in the waveguide tube 20 and propagated in a TE01 mode is converted from an electromagnetic field mode of the waveguide tube 20 to a TEM mode and divided into four signals via the first input conversion pin 40-1 to the fourth input conversion pin 40-4.

The first high-frequency signal obtained by dividing it into four is transmitted to the input terminal 11 of the first high-frequency amplifier 10-1 via the first input signal wiring layer 32-1 and a through hole 38a in the first substrate 30-1 and a solder ball 60a.

The signal input to the input terminal 11 of the first high-frequency amplifier 10-1 is amplified by the first high-frequency amplifier 10-1, and is output as an amplified high-frequency signal from the output terminal 12 of the first high-frequency amplifier 10-1.

The amplified high-frequency signal output from the output terminal 12 of the first high-frequency amplifier 10-1 is transmitted to the first output conversion pin 50-1 via a solder ball 60b, and a through hole 38b and the first output signal wiring layer 33-1 in the first substrate 30-1.

The second high-frequency signal obtained by dividing it into four is transmitted to the input terminal 11 of the second high-frequency amplifier 10-2 via the second input signal wiring layer 32-2 and a through hole 38a in the first substrate 30-1 and a solder ball 60a.

The signal input to the input terminal 11 of the second high-frequency amplifier 10-2 is amplified by the second high-frequency amplifier 10-2, and is output as an amplified high-frequency signal from the output terminal 12 of the second high-frequency amplifier 10-2.

The amplified high-frequency signal output from the output terminal 12 of the second high-frequency amplifier 10-2 is transmitted to the second output conversion pin 50-2 via a solder ball 60b, and a through hole 38b and the second output signal wiring layer 33-2 in the first substrate 30-1.

The third high-frequency signal obtained by dividing it into four is transmitted to the input terminal 11 of the third high-frequency amplifier 10-3 via the third input signal wiring layer 32-3 and a through hole 38a in the second substrate 30-2 and a solder ball 60a.

The signal input to the input terminal 11 of the third high-frequency amplifier 10-3 is amplified by the third high-frequency amplifier 10-3, and is output as an amplified high-frequency signal from the output terminal 12 of the third high-frequency amplifier 10-3.

The amplified high-frequency signal output from the output terminal 12 of the third high-frequency amplifier 10-3 is transmitted to the third output conversion pin 50-3 via a solder ball 60b, and a through hole 38b and the third output signal wiring layer 33-3 in the second substrate 30-2.

The fourth high-frequency signal obtained by dividing it into four is transmitted to the input terminal 11 of the fourth high-frequency amplifier 10-4 via the fourth input signal wiring layer 32-4 and a through hole 38a in the second substrate 30-2 and a solder ball 60a.

The signal input to the input terminal 11 of the fourth high-frequency amplifier 10-4 is amplified by the fourth high-frequency amplifier 10-4, and is output as an amplified high-frequency signal from the output terminal 12 of the fourth high-frequency amplifier 10-4.

The amplified high-frequency signal output from the output terminal 12 of the fourth high-frequency amplifier 10-4 is transmitted to the fourth output conversion pin 50-4 via a solder ball 60b, and a through hole 38b and the fourth output signal wiring layer 33-4 in the second substrate 30-2.

The signals amplified by the first high-frequency amplifier 10-1 to the fourth high-frequency amplifier 10-4 and transmitted to the first output conversion pin 50-1 to the fourth output conversion pins 50-4 are converted from the TEM mode to a TE01 mode via the first output conversion pin 50-1 to the fourth output conversion pins 50-4, respectively, the four converted signals are combined, and the combined signal is output from a second end opening of the output waveguide tube 22.

In the first storage portion 20e-1 and the second storage portion 20e-2, heat generated by the first high-frequency amplifier 10-1 and the second high-frequency amplifier 10-2 is transmitted to bottom surfaces of the first storage portion 20e-1 and the second storage portion 20e-2 in close contact with the input and output common terminals 13 formed of metal layers of the first high-frequency amplifier 10-1 and the second high-frequency amplifier 10-2, respectively, and is dissipated from both side faces of the upper wall 20a of the waveguide tube 20 to outside air.

In the third storage portion 20e-3 and the fourth storage portion 20e-4, heat generated by the third high-frequency amplifier 10-3 and the fourth high-frequency amplifier 10-4 is transmitted to bottom surfaces of the third storage portion 20e-3 and the fourth storage portion 20e-4 in close contact with the input and output common terminals 13 formed of metal layers of the third high-frequency amplifier 10-3 and the fourth high-frequency amplifier 10-4, respectively, and is dissipated from both side faces of the lower wall 20b of the waveguide tube 20 to outside air.

Since the first high-frequency amplifier 10-1 is surrounded by a side face constituting the first storage portion 20e-1, and the first front surface side shield layer 34-1 and the plurality of through holes 38c formed in such a way as to surround the first storage portion 20e-1 in the first substrate 30-1, unnecessary emission of an unnecessary electromagnetic wave emitted from one main surface of the first high-frequency amplifier 10-1 to a space outside the first substrate 30-1 can be suppressed without shielding the first high-frequency amplifier 10-1 with a metal cover.

Since the second high-frequency amplifier 10-2 is surrounded by a side face constituting the second storage portion 20e-2, and the first front surface side shield layer 34-1 and the plurality of through holes 38c formed in such a way as to surround the second storage portion 20e-2 in the first substrate 30-1, unnecessary emission of an unnecessary electromagnetic wave emitted from one main surface of the second high-frequency amplifier 10-2 to a space outside the first substrate 30-1 can be suppressed without shielding the second high-frequency amplifier 10-2 with a metal cover.

Since the third high-frequency amplifier 10-3 is surrounded by a side face constituting the third storage portion 20e-3, and the second front surface side shield layer 34-2 and the plurality of through holes 38c formed in such a way as to surround the third storage portion 20e-3 in the second substrate 30-2, unnecessary emission of an unnecessary electromagnetic wave emitted from one main surface of the third high-frequency amplifier 10-3 to a space outside the second substrate 30-2 can be suppressed without shielding the third high-frequency amplifier 10-3 with a metal cover.

Since the fourth high-frequency amplifier 10-4 is surrounded by a side face constituting the fourth storage portion 20e-4, and the second front surface side shield layer 34-2 and the plurality of through holes 38c formed in such a way as to surround the fourth storage portion 20e-4 in the second substrate 30-2, unnecessary emission of an unnecessary electromagnetic wave emitted from one main surface of the fourth high-frequency amplifier 10-4 to a space outside the second substrate 30-2 can be suppressed without shielding the fourth high-frequency amplifier 10-4 with a metal cover.

The depth of each of the first storage portion 20e-1 to the fourth storage portion 20e-4 and the width thereof in a direction orthogonal to a straight line on which the input terminal 11 and the output terminal 12 of each of the first high-frequency amplifier 10-1 to the fourth high-frequency amplifier 10-4 are disposed on a plane including the straight line are each set to a value equal to or less than ½ of a wavelength λ of a frequency of a signal input to each of the first high-frequency amplifier 10-1 to the fourth high-frequency amplifier 10-4. Therefore, an electromagnetic wave having a frequency equal to or less than a frequency of a signal input to each of the first high-frequency amplifier 10-1 to the fourth high-frequency amplifier 10-4 is hardly propagated between the input terminal 11 and the output terminal 12 of each of the first high-frequency amplifier 10-1 to the fourth high-frequency amplifier 10-4 via a space of each of the first storage portion 20e-1 to the fourth storage portion 20e-4, and oscillation between the input terminal 11 and the output terminal 12 can be suppressed.

As described above, in the power amplification high-frequency circuit device according to the fifth embodiment, as in the power amplification high-frequency circuit device according to the first embodiment, heat generated by each of the first high-frequency amplifier 10-1 to the fourth high-frequency amplifier 10-4 can be dissipated from the upper wall 20a and the lower wall 20b of the waveguide tube 20 to outside air, emission of an unnecessary electromagnetic wave emitted from each of the first high-frequency amplifier 10-1 to the fourth high-frequency amplifier 10-4 to a space outside the first substrate 30-1 and the second substrate 30-2 can be suppressed, and oscillation between the input terminal 11 and the output terminal 12 due to an electromagnetic wave having a frequency equal to or less than ½ of a wavelength λ of a frequency of an input signal can be suppressed.

In the power amplification high-frequency circuit device according to the fifth embodiment, the first high-frequency amplifier 10-1 and the second high-frequency amplifier 10-2 are stored in the first storage portion 20e-1 and the second storage portion 20e-2 in the upper wall 20a of the waveguide tube 20, respectively, and the third high-frequency amplifier 10-3 and the fourth high-frequency amplifier 10-4 are stored in the third storage portion 20e-3 and the fourth storage portion 20e-4 in the lower wall 20b of the waveguide tube 20, respectively. Therefore, the first high-frequency amplifier 10-1 to the fourth high-frequency amplifier 10-4 serving as heat sources can be dispersed, and four signals amplified by the first high-frequency amplifier 10-1 to the fourth high-frequency amplifier 10-4 can be combined.

In addition, the interval OD1 between the first output conversion pin 50-1 and the second output conversion pin 50-2 is narrower than the interval OD2 between the output terminal 12 in the first high-frequency amplifier 10-1 and the output terminal 12 in the second high-frequency amplifier 10-2, and the interval OD1 between the third output conversion pin 50-3 and the fourth output conversion pin 50-4 is narrower than the interval OD2 between the output terminal 12 in the third high-frequency amplifier 10-3 and the output terminal 12 in the fourth high-frequency amplifier 10-4. Therefore, the amount of insertion into the output waveguide tube 22 can be shortened by disposing the first output conversion pin 50-1 to the fourth output conversion pin 50-4 near the tube axis.

As a result, a distance between facing distal ends of the first output conversion pin 50-1 and the third output conversion pin 50-3 can be increased. Therefore, discharge between the facing distal ends of the first output conversion pin 50-1 and the third output conversion pin 50-3 can be suppressed. In addition, a distance between facing distal ends of the second output conversion pin 50-2 and the fourth output conversion pin 50-4 can be increased. Therefore, discharge between the facing distal ends of the second output conversion pin 50-2 and the fourth output conversion pin 50-4 can be suppressed.

Furthermore, the distance OD2 between the first high-frequency amplifier 10-1 and the second high-frequency amplifier 10-2 is wider than the interval OD1 between the first output conversion pin 50-1 and the second output conversion pin 50-2. Therefore, the upper wall 20a between the first high-frequency amplifier 10-1 and the second high-frequency amplifier 10-2 can be widened. Therefore, heat generated by the first high-frequency amplifier 10-1 and the second high-frequency amplifier 10-2 can be efficiently dissipated to both side faces of the upper wall 20a of the waveguide tube 20.

In addition, the distance OD2 between the third high-frequency amplifier 10-3 and the fourth high-frequency amplifier 10-4 is wider than the interval OD1 between the third output conversion pin 50-3 and the fourth output conversion pin 50-4. Therefore, the lower wall 20b between the third high-frequency amplifier 10-3 and the fourth high-frequency amplifier 10-4 can be widened. Therefore, heat generated by the third high-frequency amplifier 10-3 and the fourth high-frequency amplifier 10-4 can be efficiently dissipated to both side faces of the lower wall 20b of the waveguide tube 20.

The first storage portion 20e-1 to the fourth storage portion 20e-4 are located on the output waveguide tube 22 side, a distance between the output terminal 12 of the first high-frequency amplifier 10-1 and the first output conversion pin 50-1, a distance between the output terminal 12 of the second high-frequency amplifier 10-2 and the second output conversion pin 50-2, a distance between the output terminal 12 of the third high-frequency amplifier 10-3 and the third output conversion pin 50-3, and a distance between the output terminal 12 of the fourth high-frequency amplifier 10-4 and the fourth output conversion pin 50-4 are shortened, and the length of each of the first output signal wiring layer 33-1 to the fourth output signal wiring layer 33-4 is set to a minimum wiring length required for a matching circuit. As a result, a loss in each of the first output signal wiring layer 33-1 to the fourth output signal wiring layer 33-4 can be reduced.

Note that, similarly to the upper wall 20a of the waveguide tube 20 in the power amplification high-frequency circuit device according to the second embodiment, the upper wall 20a of the waveguide tube 20 in the power amplification high-frequency circuit device according to the fifth embodiment may have a lower portion upper wall and an upper portion upper wall whose inner wall surface is closely fixed to an outer wall surface of the lower portion upper wall and which is a plate-shaped conductive plate, the upper portion upper wall may have two penetration holes formed in parallel at a central portion thereof, and regions surrounded by the two penetration holes in the upper portion upper wall and the outer wall surface of the lower portion upper wall may be used as the first storage portion 20e-1 and the second storage portion 20e-2, respectively.

Similarly to the upper wall 20a, the lower wall 20b of the waveguide tube 20 in the power amplification high-frequency circuit device according to the fifth embodiment may also include a lower portion lower wall and an upper portion lower wall whose inner wall surface is closely fixed to an outer wall surface of the lower portion lower wall and which is a plate-shaped conductive plate, the upper portion lower wall may have two penetration holes formed in parallel at a central portion thereof, and regions surrounded by the two penetration holes in the upper portion lower wall and the outer wall surface of the lower portion lower wall may be used as the third storage portion 20e-3 and the fourth storage portion 20e-4, respectively.

In addition, in the power amplification high-frequency circuit device according to the fifth embodiment, as in the power amplification high-frequency circuit device according to the third embodiment, an additional upper wall 21a3 may be formed on a lower side of the upper wall 21a of the input waveguide tube 21, a distance between an inner wall surface of the upper wall 21a of the input waveguide tube 21 and an inner wall surface of the lower wall 21b may be shorter than a distance between an inner wall surface of the upper wall 22a of the output waveguide tube 22 and an inner wall surface of the lower wall 22b, and the wall thickness of the upper wall 21a of the input waveguide tube 21 may be larger than the wall thickness of the upper wall 22a of the output waveguide tube 22.

Furthermore, the power amplification high-frequency circuit device according to the fifth embodiment may have the following configuration similarly to the power amplification high-frequency circuit device according to the fourth embodiment.

That is, the width of the first storage portion 20e-1 in a direction of a straight line on which the input terminal 11 and the output terminal 12 of the first high-frequency amplifier 10-1 are disposed may be set to a length including the first input pin insertion hole 21e-1 into which the first input conversion pin 40a-1 is inserted and the first output pin insertion hole 22e-1 into which the first output conversion pin 50a-1 is inserted, the first input conversion pin 40a-1 and the first output conversion pin 50a-1 may be spring probes, and the first input signal wiring layer 32-1 and the first output signal wiring layer 33-1 in the first substrate 30-1 may be disposed on a back surface of the first insulating substrate 31-1.

The width of the second storage portion 20e-2 in a direction of a straight line on which the input terminal 11 and the output terminal 12 of the second high-frequency amplifier 10-2 are disposed may be set to a length including the second input pin insertion hole 21e-2 into which the second input conversion pin 40a-2 is inserted and the second output pin insertion hole 22e-2 into which the second output conversion pin 50a-2 is inserted, the second input conversion pin 40a-2 and the second output conversion pin 50a-2 may be spring probes, and the second input signal wiring layer 32-2 and the second output signal wiring layer 33-2 in the first substrate 30-1 may be disposed on a back surface of the first insulating substrate 31-1.

The width of the third storage portion 20e-3 in a direction of a straight line on which the input terminal 11 and the output terminal 12 of the third high-frequency amplifier 10-3 are disposed may be set to a length including the third input pin insertion hole 21e-3 into which the third input conversion pin 40a-3 is inserted and the third output pin insertion hole 22e-3 into which the third output conversion pin 50a-3 is inserted, the third input conversion pin 40a-3 and the third output conversion pin 50a-3 may be spring probes, and the third input signal wiring layer 32-3 and the third output signal wiring layer 33-3 in the second substrate 30-2 may be disposed on a back surface of the second insulating substrate 31-2.

The width of the fourth storage portion 20e-4 in a direction of a straight line on which the input terminal 11 and the output terminal 12 of the fourth high-frequency amplifier 10-4 are disposed may be set to a length including the fourth input pin insertion hole 21e-4 into which the fourth input conversion pin 40a-4 is inserted and the fourth output pin insertion hole 22e-4 into which the fourth output conversion pin 50a-4 is inserted, the fourth input conversion pin 40a-4 and the fourth output conversion pin 50a-4 may be spring probes, and the fourth input signal wiring layer 32-4 and the fourth output signal wiring layer 33-4 in the second substrate 30-2 may be disposed on a back surface of the second insulating substrate 31-2.

Note that the embodiments can be freely combined to each other, any constituent element in each of the embodiments can be modified, or any constituent element in each of the embodiments can be omitted.

### INDUSTRIAL APPLICABILITY

The power amplification high-frequency circuit device according to the present disclosure includes: a waveguide tube including an input waveguide tube, an output waveguide tube, and a short wall; and a high-frequency amplifier, and is suitable for a power amplification high-frequency circuit device that converts an electromagnetic wave incident on a first end opening of the input waveguide tube from a TE01 mode to a TEM mode, amplifies the converted electromagnetic wave by the high-frequency amplifier, then converts the amplified signal from the TEM mode to the TE01 mode, and outputs the converted signal as an electromagnetic wave from a second end opening of the output waveguide tube.

### REFERENCE SIGNS LIST

10 and 10-1 to 10-4: High-frequency amplifier, 11: Input terminal, 12: Output terminal, 13: Input and output common terminal, 20: Waveguide tube, 20a: Upper wall, 20b: Lower wall, 20c and 20d: Side wall, 20e, 20e1, and 20e-1 to 20e-4: Storage portion, 21: Input waveguide tube, 21e and 21e-1 to 21e-4: Insertion hole, 22: Output waveguide tube, 22e and 22e-1 to 22e-4: Insertion hole, 23: Short wall, 30, 30-1, and 30-2: Substrate, 31: Insulating substrate, 32 and 32-1 to 32-4: Input signal wiring layer, 33 and 33-1 to 33-4: Output signal wiring layer, 34: Front surface side shield layer, 35 and 35-1 to 35-4: Input signal land, 36 and 36-1 to 36-4: Output signal land, 37: Back surface side shield layer, 38a to 38c: Through hole, 40, 40a, and 40-1 to 40-4: Input conversion pin, 50, 50a, and 50-1 to 50-4: Output conversion pin, 60a and 60b: Solder ball, 70a and 70b: Solder

1. A power amplification high-frequency circuit device comprising:
an input conversion pin;
an output conversion pin;
a high-frequency amplifier having an input terminal and an output terminal;
a waveguide tube including an input waveguide tube, an output waveguide tube, and a short wall, in which the input waveguide tube and the output waveguide tube are disposed in such a way as to face each other with the short wall interposed between the input waveguide tube and the output waveguide tube, an upper wall of the input waveguide tube has an input pin insertion hole into which the input conversion pin is inserted while being electrically insulated in such a manner that a first end of the input conversion pin protrudes inward and a second end of the input conversion pin protrudes outward, an upper wall of the output waveguide tube has an output pin insertion hole into which the output conversion pin is inserted while being electrically insulated in such a manner that a first end of the output conversion pin protrudes inward and a second end of the output conversion pin protrudes outward, an upper wall thereof has a storage portion whose depth from an outer wall surface of the upper wall is deeper than the height of the high-frequency amplifier and which has a flat bottom surface, and the high-frequency amplifier is stored in the storage portion with a bottom surface of the high-frequency amplifier being in close contact with the bottom surface of the storage portion; and
a substrate including an insulating substrate having, on a back surface of the insulating substrate, input signal wiring whose first end portion is electrically connected to the input conversion pin and whose second end portion is electrically connected to the input terminal of the high-frequency amplifier, and output signal wiring whose first end portion is electrically connected to the output terminal of the high-frequency amplifier and whose second end portion is electrically connected to the output conversion pin,
wherein a width of the storage portion in a direction of a straight line on which the input terminal and the output terminal of the high-frequency amplifier are disposed is set to a length including the input pin insertion hole into which the input conversion pin is inserted and which is formed in the upper wall of the input waveguide tube, and the output pin insertion hole into which the output conversion pin is inserted and which is formed in the upper wall of the output waveguide tube,
the input signal wiring and the output signal wiring are disposed on the back surface of the insulating substrate,
the input conversion pin is a spring probe which is inserted into the input pin insertion hole into which the input conversion pin is inserted and which is formed in the upper wall of the input waveguide tube, and is fixed to the upper wall of the input waveguide tube, and a distal end of which is brought into close contact with the input signal wiring by an elastic force and electrically connected to the input signal wiring, and
the output conversion pin is a spring probe which is inserted into the output pin insertion hole into which the output conversion pin is inserted and which is formed in the upper wall of the output waveguide tube, and is fixed to the upper wall of the output waveguide tube, and a distal end of which is brought into close contact with the output signal wiring by an elastic force and electrically connected to the output signal wiring.

2. A power amplification high-frequency circuit device comprising:
an input conversion pin;
an output conversion pin;
a high-frequency amplifier having an input terminal and an output terminal;
a waveguide tube including an input waveguide tube, an output waveguide tube, and a short wall, in which the input waveguide tube and the output waveguide tube are disposed in such a way as to face each other with the short wall interposed between the input waveguide tube and the output waveguide tube, an upper wall of the input waveguide tube has an input pin insertion hole into which the input conversion pin is inserted while being electrically insulated in such a manner that a first end of the input conversion pin protrudes inward and a second end of the input conversion pin protrudes outward, an upper wall of the output waveguide tube has an output pin insertion hole into which the output conversion pin is inserted while being electrically insulated in such a manner that a first end of the output conversion pin protrudes inward and a second end of the output conversion pin protrudes outward, an upper wall thereof has a storage portion whose depth from an outer wall surface of the upper wall is deeper than the height of the high-frequency amplifier and which has a flat bottom surface, and the high-frequency amplifier is stored in the storage portion with a bottom surface of the high-frequency amplifier being in close contact with the bottom surface of the storage portion; and
a substrate including an insulating substrate having, on a back surface of the insulating substrate, input signal wiring whose first end portion is electrically connected to the input conversion pin and whose second end portion is electrically connected to the input terminal of the high-frequency amplifier, and output signal wiring whose first end portion is electrically connected to the output terminal of the high-frequency amplifier and whose second end portion is electrically connected to the output conversion pin,
wherein the upper wall of the waveguide tube includes: a lower portion upper wall integrally formed with a lower wall and a pair of side walls; and an upper portion upper wall having an inner wall surface closely fixed to an outer wall surface of the lower portion upper wall, having a penetration hole in a central portion thereof, and being a plate-shaped conductive plate, and a region surrounded by the penetration hole in the upper portion upper wall and the outer wall surface of the lower portion upper wall constitutes the storage portion.

3. The power amplification high-frequency circuit device according to claim 2, wherein the conductive plate constituting the upper portion upper wall is a conductive elastic body.

4. A power amplification high-frequency circuit device comprising:
an input conversion pin;
an output conversion pin;
a high-frequency amplifier having an input terminal and an output terminal;
a waveguide tube including an input waveguide tube, an output waveguide tube, and a short wall, in which the input waveguide tube and the output waveguide tube are disposed in such a way as to face each other with the short wall interposed between the input waveguide tube and the output waveguide tube, an upper wall of the input waveguide tube has an input pin insertion hole into which the input conversion pin is inserted while being electrically insulated in such a manner that a first end of the input conversion pin protrudes inward and a second end of the input conversion pin protrudes outward, an upper wall of the output waveguide tube has an output pin insertion hole into which the output conversion pin is inserted while being electrically insulated in such a manner that a first end of the output conversion pin protrudes inward and a second end of the output conversion pin protrudes outward, an upper wall thereof has a storage portion whose depth from an outer wall surface of the upper wall is deeper than the height of the high-frequency amplifier and which has a flat bottom surface, and the high-frequency amplifier is stored in the storage portion with a bottom surface of the high-frequency amplifier being in close contact with the bottom surface of the storage portion; and
a substrate including an insulating substrate having, on a back surface of the insulating substrate, input signal wiring whose first end portion is electrically connected to the input conversion pin and whose second end portion is electrically connected to the input terminal of the high-frequency amplifier, and output signal wiring whose first end portion is electrically connected to the output terminal of the high-frequency amplifier and whose second end portion is electrically connected to the output conversion pin,
wherein a distance between an inner wall surface of an upper wall of the input waveguide tube and an inner wall surface of a lower wall facing the upper wall is shorter than a distance between an inner wall surface of an upper wall of the output waveguide tube and an inner wall surface of a lower wall facing the upper wall, and a wall thickness of the upper wall of the input waveguide tube is larger than a wall thickness of the upper wall of the output waveguide tube.

5. The power amplification high-frequency circuit device according to claim 2, wherein
the substrate has: an input pin insertion hole communicating with the input pin insertion hole formed in the upper wall of the input waveguide tube into which the input conversion pin is inserted; and an output pin insertion hole communicating with the output pin insertion hole formed in the upper wall of the output waveguide tube into which the output conversion pin is inserted, and
the input signal wiring and the output signal wiring are disposed on a surface of the insulating substrate while being electrically insulated from a front surface side shield layer.

6. The power amplification high-frequency circuit device according to claim 2, wherein
a width of the storage portion in a direction of a straight line on which the input terminal and the output terminal of the high-frequency amplifier are disposed is set to a length including the input pin insertion hole into which the input conversion pin is inserted and which is formed in the upper wall of the input waveguide tube, and the output pin insertion hole into which the output conversion pin is inserted and which is formed in the upper wall of the output waveguide tube,
the input signal wiring and the output signal wiring are disposed on the back surface of the insulating substrate,
the input conversion pin is a spring probe which is inserted into the input pin insertion hole into which the input conversion pin is inserted and which is formed in the upper wall of the input waveguide tube, and is fixed to the upper wall of the input waveguide tube, and a distal end of which is brought into close contact with the input signal wiring by an elastic force and electrically connected to the input signal wiring, and
the output conversion pin is a spring probe which is inserted into the output pin insertion hole into which the output conversion pin is inserted and which is formed in the upper wall of the output waveguide tube, and is fixed to the upper wall of the output waveguide tube, and a distal end of which is brought into close contact with the output signal wiring by an elastic force and electrically connected to the output signal wiring.

7. The power amplification high-frequency circuit device according to claim 1, wherein a depth of the storage portion and a width of the storage portion in a direction orthogonal to a straight line on which the input terminal and the output terminal of the high-frequency amplifier are disposed on a plane including the straight line are each set to a value equal to or less than ½ of a wavelength λ of a frequency of a signal input to the high-frequency amplifier.

8. The power amplification high-frequency circuit device according to claim 1, wherein the substrate includes: a front surface side shield layer disposed on a front surface that is one surface of the insulating substrate, extending to a peripheral portion of the insulating substrate, and set to a ground potential; a back surface side shield layer disposed on the back surface of the insulating substrate, disposed in close contact with a wall surface of an upper wall of the waveguide tube excluding the storage portion, extending to a peripheral portion of the insulating substrate, and set to a ground potential; and a plurality of through holes formed along a peripheral portion of the insulating substrate and electrically connecting the front surface side shield layer to the back surface side shield layer.

9. The power amplification high-frequency circuit device according to claim 1, wherein a length of the output signal wiring is a minimum wiring length required for matching between the output terminal of the high-frequency amplifier and the output waveguide tube.

10. A power amplification high-frequency circuit device comprising:
a first input conversion pin to a fourth input conversion pin;
a first output conversion pin to a fourth output conversion pin;
a first high-frequency amplifier to a fourth high-frequency amplifier each having an input terminal and an output terminal;
a waveguide tube including an input waveguide tube, an output waveguide tube, and a short wall, in which the input waveguide tube and the output waveguide tube are disposed in such a way as to face each other with the short wall interposed between the input waveguide tube and the output waveguide tube, an upper wall of the input waveguide tube has: a first input pin insertion hole into which the first input conversion pin is inserted while being electrically insulated in such a manner that a first end of the first input conversion pin protrudes inward and a second end of the first input conversion pin protrudes outward; and a second input pin insertion hole which is disposed on a straight line in a direction orthogonal to a tube axis with an interval from the first input pin insertion hole and into which the second input conversion pin is inserted while being electrically insulated in such a manner that a first end of the second input conversion pin protrudes inward and a second end of the second input conversion pin protrudes outward, an upper wall of the output waveguide tube has: a first output pin insertion hole into which the first output conversion pin is inserted while being electrically insulated in such a manner that a first end of the first output conversion pin protrudes inward and a second end of the first output conversion pin protrudes outward; and a second output pin insertion hole which is disposed on a straight line in a direction orthogonal to the tube axis with an interval from the first output pin insertion hole and into which the second output conversion pin is inserted while being electrically insulated in such a manner that a first end of the second output conversion pin protrudes inward and a second end of the second output conversion pin protrudes outward, an upper wall thereof has a first storage portion and a second storage portion whose depths from an outer wall surface of the upper wall are deeper than heights of the first high-frequency amplifier and the second high-frequency amplifier, respectively, which have flat bottom surfaces, and which are disposed in parallel on a straight line in a direction orthogonal to the tube axis, the first high-frequency amplifier is stored in the first storage portion with a bottom surface of the first high-frequency amplifier being in close contact with the bottom surface of the first storage portion, the second high-frequency amplifier is stored in the second storage portion with a bottom surface of the second high-frequency amplifier being in close contact with the bottom surface of the second storage portion,
a lower wall of the input waveguide tube has: a third input pin insertion hole into which the third input conversion pin is inserted while being electrically insulated in such a manner that a first end of the third input conversion pin protrudes inward and a second end of the third input conversion pin protrudes outward; and a fourth input pin insertion hole which is disposed on a straight line in a direction orthogonal to the tube axis with an interval from the third input pin insertion hole and into which the fourth input conversion pin is inserted while being electrically insulated in such a manner that a first end of the fourth input conversion pin protrudes inward and a second end of the fourth input conversion pin protrudes outward, a lower wall of the output waveguide tube has: a third output pin insertion hole into which the third output conversion pin is inserted while being electrically insulated in such a manner that a first end of the third output conversion pin protrudes inward and a second end of the third output conversion pin protrudes outward; and a fourth output pin insertion hole which is disposed on a straight line in a direction orthogonal to the tube axis with an interval from the third output pin insertion hole and into which the fourth output conversion pin is inserted while being electrically insulated in such a manner that a first end of the fourth output conversion pin protrudes inward and a second end of the fourth output conversion pin protrudes outward, a lower wall thereof has a third storage portion and a fourth storage portion whose depths from an outer wall surface of the lower wall are deeper than heights of the third high-frequency amplifier and the fourth high-frequency amplifier, respectively, which have flat bottom surfaces, and which are disposed in parallel on a straight line in a direction orthogonal to the tube axis, the third high-frequency amplifier is stored in the third storage portion with a bottom surface of the third high-frequency amplifier being in close contact with the bottom surface of the third storage portion, and the fourth high-frequency amplifier is stored in the fourth storage portion with a bottom surface of the fourth high-frequency amplifier being in close contact with the bottom surface of the fourth storage portion;
a first substrate including a first insulating substrate having, on a back surface of the first insulating substrate, first input signal wiring whose first end portion is electrically connected to the first input conversion pin and whose second end portion is electrically connected to the input terminal of the first high-frequency amplifier, first output signal wiring whose first end portion is electrically connected to the output terminal of the first high-frequency amplifier and whose second end portion is electrically connected to the first output conversion pin, second input signal wiring whose first end portion is electrically connected to the second input conversion pin and whose second end portion is electrically connected to the input terminal of the second high-frequency amplifier, and second output signal wiring whose first end portion is electrically connected to the output terminal of the second high-frequency amplifier and whose second end portion is electrically connected to the second output conversion pin; and
a second substrate including a second insulating substrate having, on a back surface of the second insulating substrate, third input signal wiring whose first end portion is electrically connected to the third input conversion pin and whose second end portion is electrically connected to the input terminal of the third high-frequency amplifier, third output signal wiring whose first end portion is electrically connected to the output terminal of the third high-frequency amplifier and whose second end portion is electrically connected to the third output conversion pin, fourth input signal wiring whose first end portion is electrically connected to the fourth input conversion pin and whose second end portion is electrically connected to the input terminal of the fourth high-frequency amplifier, and fourth output signal wiring whose first end portion is electrically connected to the output terminal of the fourth high-frequency amplifier and whose second end portion is electrically connected to the fourth output conversion pin,
wherein widths of the first storage portion and the second storage portion in a direction of a straight line on which the input terminals and the output terminals of the corresponding first high-frequency amplifier and the second high-frequency amplifier are disposed are set to lengths including the corresponding first input pin insertion hole and second input pin insertion hole into which the corresponding first input conversion pin and second input conversion pin are inserted and which are formed in the upper wall of the input waveguide tube, and the corresponding first output pin insertion hole and second output pin insertion hole into which the corresponding first output conversion pin and second output conversion pin are inserted and which are formed in the upper wall of the output waveguide tube, respectively,
the first input signal wiring, the first output signal wiring, the second input signal wiring, and the second output signal wiring are disposed on the back surface of the first insulating substrate,
the first input conversion pin and the second input conversion pin are spring probes which are inserted into the corresponding first input pin insertion hole and second input pin insertion hole into which the first input conversion pin and the second input conversion pin are inserted and which are formed in the upper wall of the input waveguide tube, and are fixed to the upper wall of the input waveguide tube, and distal ends of which are brought into close contact with the corresponding first input signal wiring and second input signal wiring by an elastic force and electrically connected to the first input signal wiring and the second input signal wiring, respectively,
the first output conversion pin and the second output conversion pin are spring probes which are inserted into the corresponding first output pin insertion hole and second output pin insertion hole into which the first output conversion pin and the second output conversion pin are inserted and which are formed in the upper wall of the output waveguide tube, and are fixed to the upper wall of the output waveguide tube, and distal ends of which are brought into close contact with the corresponding first output signal wiring and second output signal wiring by an elastic force and electrically connected to the first output signal wiring and the second output signal wiring, respectively,
widths of the third storage portion and the fourth storage portion in a direction of a straight line on which the input terminals and the output terminals of the corresponding third high-frequency amplifier and fourth high-frequency amplifier are disposed are set to lengths including the corresponding third input pin insertion hole and fourth input pin insertion hole into which the corresponding third input conversion pin and fourth input conversion pin are inserted and which are formed in the lower wall of the input waveguide tube, and the corresponding third output pin insertion hole and the fourth output pin insertion hole into which the corresponding third output conversion pin and fourth output conversion pin are inserted and which are formed in the lower wall of the output waveguide tube, respectively,
the third input signal wiring, the third output signal wiring, the fourth input signal wiring, and the fourth output signal wiring are disposed on the back surface of the second insulating substrate,
the third input conversion pin and the fourth input conversion pin are spring probes which are inserted into the corresponding third input pin insertion hole and fourth input pin insertion hole into which the third input conversion pin and the fourth input conversion pin are inserted and which are formed in the lower wall of the input waveguide tube, and are fixed to the lower wall of the input waveguide tube, and distal ends of which are brought into close contact with the corresponding third input signal wiring and fourth input signal wiring by an elastic force and electrically connected to the third input signal wiring and the fourth input signal wiring, respectively, and
the third output conversion pin and the fourth output conversion pin are spring probes which are inserted into the corresponding third output pin insertion hole and fourth output pin insertion hole into which the third output conversion pin and the fourth output conversion pin are inserted and which are formed in the lower wall of the output waveguide tube, and are fixed to the lower wall of the output waveguide tube, and distal ends of which are brought into close contact with the corresponding third output signal wiring and the fourth output signal wiring by an elastic force and electrically connected to the third output signal wiring and the fourth output signal wiring, respectively.

11. A power amplification high-frequency circuit device comprising:
a first input conversion pin to a fourth input conversion pin;
a first output conversion pin to a fourth output conversion pin;
a first high-frequency amplifier to a fourth high-frequency amplifier each having an input terminal and an output terminal;
a waveguide tube including an input waveguide tube, an output waveguide tube, and a short wall, in which the input waveguide tube and the output waveguide tube are disposed in such a way as to face each other with the short wall interposed between the input waveguide tube and the output waveguide tube, an upper wall of the input waveguide tube has: a first input pin insertion hole into which the first input conversion pin is inserted while being electrically insulated in such a manner that a first end of the first input conversion pin protrudes inward and a second end of the first input conversion pin protrudes outward; and a second input pin insertion hole which is disposed on a straight line in a direction orthogonal to a tube axis with an interval from the first input pin insertion hole and into which the second input conversion pin is inserted while being electrically insulated in such a manner that a first end of the second input conversion pin protrudes inward and a second end of the second input conversion pin protrudes outward, an upper wall of the output waveguide tube has: a first output pin insertion hole into which the first output conversion pin is inserted while being electrically insulated in such a manner that a first end of the first output conversion pin protrudes inward and a second end of the first output conversion pin protrudes outward; and a second output pin insertion hole which is disposed on a straight line in a direction orthogonal to the tube axis with an interval from the first output pin insertion hole and into which the second output conversion pin is inserted while being electrically insulated in such a manner that a first end of the second output conversion pin protrudes inward and a second end of the second output conversion pin protrudes outward, an upper wall thereof has a first storage portion and a second storage portion whose depths from an outer wall surface of the upper wall are deeper than heights of the first high-frequency amplifier and the second high-frequency amplifier, respectively, which have flat bottom surfaces, and which are disposed in parallel on a straight line in a direction orthogonal to the tube axis, the first high-frequency amplifier is stored in the first storage portion with a bottom surface of the first high-frequency amplifier being in close contact with the bottom surface of the first storage portion, the second high-frequency amplifier is stored in the second storage portion with a bottom surface of the second high-frequency amplifier being in close contact with the bottom surface of the second storage portion,
a lower wall of the input waveguide tube has: a third input pin insertion hole into which the third input conversion pin is inserted while being electrically insulated in such a manner that a first end of the third input conversion pin protrudes inward and a second end of the third input conversion pin protrudes outward; and a fourth input pin insertion hole which is disposed on a straight line in a direction orthogonal to the tube axis with an interval from the third input pin insertion hole and into which the fourth input conversion pin is inserted while being electrically insulated in such a manner that a first end of the fourth input conversion pin protrudes inward and a second end of the fourth input conversion pin protrudes outward, a lower wall of the output waveguide tube has: a third output pin insertion hole into which the third output conversion pin is inserted while being electrically insulated in such a manner that a first end of the third output conversion pin protrudes inward and a second end of the third output conversion pin protrudes outward; and a fourth output pin insertion hole which is disposed on a straight line in a direction orthogonal to the tube axis with an interval from the third output pin insertion hole and into which the fourth output conversion pin is inserted while being electrically insulated in such a manner that a first end of the fourth output conversion pin protrudes inward and a second end of the fourth output conversion pin protrudes outward, a lower wall thereof has a third storage portion and a fourth storage portion whose depths from an outer wall surface of the lower wall are deeper than heights of the third high-frequency amplifier and the fourth high-frequency amplifier, respectively, which have flat bottom surfaces, and which are disposed in parallel on a straight line in a direction orthogonal to the tube axis, the third high-frequency amplifier is stored in the third storage portion with a bottom surface of the third high-frequency amplifier being in close contact with the bottom surface of the third storage portion, and the fourth high-frequency amplifier is stored in the fourth storage portion with a bottom surface of the fourth high-frequency amplifier being in close contact with the bottom surface of the fourth storage portion;
a first substrate including a first insulating substrate having, on one surface of the first insulating substrate, first input signal wiring whose first end portion is electrically connected to the first input conversion pin and whose second end portion is electrically connected to the input terminal of the first high-frequency amplifier, first output signal wiring whose first end portion is electrically connected to the output terminal of the first high-frequency amplifier and whose second end portion is electrically connected to the first output conversion pin, second input signal wiring whose first end portion is electrically connected to the second input conversion pin and whose second end portion is electrically connected to the input terminal of the second high-frequency amplifier, and second output signal wiring whose first end portion is electrically connected to the output terminal of the second high-frequency amplifier and whose second end portion is electrically connected to the second output conversion pin; and
a second substrate including a second insulating substrate having, on one surface of the second insulating substrate, third input signal wiring whose first end portion is electrically connected to the third input conversion pin and whose second end portion is electrically connected to the input terminal of the third high-frequency amplifier, third output signal wiring whose first end portion is electrically connected to the output terminal of the third high-frequency amplifier and whose second end portion is electrically connected to the third output conversion pin, fourth input signal wiring whose first end portion is electrically connected to the fourth input conversion pin and whose second end portion is electrically connected to the input terminal of the fourth high-frequency amplifier, and fourth output signal wiring whose first end portion is electrically connected to the output terminal of the fourth high-frequency amplifier and whose second end portion is electrically connected to the fourth output conversion pin,
wherein the upper wall of the waveguide tube includes: a lower portion upper wall integrally formed with a lower portion lower wall and a pair of side walls; and an upper portion upper wall having an inner wall surface closely fixed to an outer wall surface of the lower portion upper wall, having a first penetration hole and a second penetration hole formed in parallel at a central portion, and being a plate-shaped conductive plate, and regions surrounded by the first penetration hole and the second penetration hole in the upper portion upper wall and the outer wall surface of the lower portion upper wall constitute the first storage portion and the second storage portion, respectively, and
the lower wall of the waveguide tube includes: the lower portion lower wall; and an upper portion lower wall having an inner wall surface closely fixed to an outer wall surface of the lower portion lower wall, having a third penetration hole and a fourth penetration hole formed in parallel at a central portion, and being a plate-shaped conductive plate, and regions surrounded by the third penetration hole and the fourth penetration hole in the upper portion lower wall and the outer wall surface of the lower portion lower wall constitute the third storage portion and the fourth storage portion, respectively.

12. The power amplification high-frequency circuit device according to claim 11, wherein the conductive plate constituting each of the upper portion upper wall and the upper portion lower wall is a conductive elastic body.

13. A power amplification high-frequency circuit device comprising:
a first input conversion pin to a fourth input conversion pin;
a first output conversion pin to a fourth output conversion pin;
a first high-frequency amplifier to a fourth high-frequency amplifier each having an input terminal and an output terminal;
a waveguide tube including an input waveguide tube, an output waveguide tube, and a short wall, in which the input waveguide tube and the output waveguide tube are disposed in such a way as to face each other with the short wall interposed between the input waveguide tube and the output waveguide tube, an upper wall of the input waveguide tube has: a first input pin insertion hole into which the first input conversion pin is inserted while being electrically insulated in such a manner that a first end of the first input conversion pin protrudes inward and a second end of the first input conversion pin protrudes outward; and a second input pin insertion hole which is disposed on a straight line in a direction orthogonal to a tube axis with an interval from the first input pin insertion hole and into which the second input conversion pin is inserted while being electrically insulated in such a manner that a first end of the second input conversion pin protrudes inward and a second end of the second input conversion pin protrudes outward, an upper wall of the output waveguide tube has: a first output pin insertion hole into which the first output conversion pin is inserted while being electrically insulated in such a manner that a first end of the first output conversion pin protrudes inward and a second end of the first output conversion pin protrudes outward, and a second output pin insertion hole which is disposed on a straight line in a direction orthogonal to the tube axis with an interval from the first output pin insertion hole and into which the second output conversion pin is inserted while being electrically insulated in such a manner that a first end of the second output conversion pin protrudes inward and a second end of the second output conversion pin protrudes outward, an upper wall thereof has a first storage portion and a second storage portion whose depths from an outer wall surface of the upper wall are deeper than heights of the first high-frequency amplifier and the second high-frequency amplifier, respectively, which have flat bottom surfaces, and which are disposed in parallel on a straight line in a direction orthogonal to the tube axis, the first high-frequency amplifier is stored in the first storage portion with a bottom surface of the first high-frequency amplifier being in close contact with the bottom surface of the first storage portion, the second high-frequency amplifier is stored in the second storage portion with a bottom surface of the second high-frequency amplifier being in close contact with the bottom surface of the second storage portion,
a lower wall of the input waveguide tube has: a third input pin insertion hole into which the third input conversion pin is inserted while being electrically insulated in such a manner that a first end of the third input conversion pin protrudes inward and a second end of the third input conversion pin protrudes outward; and a fourth input pin insertion hole which is disposed on a straight line in a direction orthogonal to the tube axis with an interval from the third input pin insertion hole and into which the fourth input conversion pin is inserted while being electrically insulated in such a manner that a first end of the fourth input conversion pin protrudes inward and a second end of the fourth input conversion pin protrudes outward, a lower wall of the output waveguide tube has: a third output pin insertion hole into which the third output conversion pin is inserted while being electrically insulated in such a manner that a first end of the third output conversion pin protrudes inward and a second end of the third output conversion pin protrudes outward; and a fourth output pin insertion hole which is disposed on a straight line in a direction orthogonal to the tube axis with an interval from the third output pin insertion hole and into which the fourth output conversion pin is inserted while being electrically insulated in such a manner that a first end of the fourth output conversion pin protrudes inward and a second end of the fourth output conversion pin protrudes outward, a lower wall thereof has a third storage portion and a fourth storage portion whose depths from an outer wall surface of the lower wall are deeper than heights of the third high-frequency amplifier and the fourth high-frequency amplifier, respectively, which have flat bottom surfaces, and which are disposed in parallel on a straight line in a direction orthogonal to the tube axis, the third high-frequency amplifier is stored in the third storage portion with a bottom surface of the third high-frequency amplifier being in close contact with the bottom surface of the third storage portion, and the fourth high-frequency amplifier is stored in the fourth storage portion with a bottom surface of the fourth high-frequency amplifier being in close contact with the bottom surface of the fourth storage portion;
a first substrate including a first insulating substrate having, on one surface of the first insulating substrate, first input signal wiring whose first end portion is electrically connected to the first input conversion pin and whose second end portion is electrically connected to the input terminal of the first high-frequency amplifier, first output signal wiring whose first end portion is electrically connected to the output terminal of the first high-frequency amplifier and whose second end portion is electrically connected to the first output conversion pin, second input signal wiring whose first end portion is electrically connected to the second input conversion pin and whose second end portion is electrically connected to the input terminal of the second high-frequency amplifier, and second output signal wiring whose first end portion is electrically connected to the output terminal of the second high-frequency amplifier and whose second end portion is electrically connected to the second output conversion pin; and
a second substrate including a second insulating substrate having, on one surface of the second insulating substrate, third input signal wiring whose first end portion is electrically connected to the third input conversion pin and whose second end portion is electrically connected to the input terminal of the third high-frequency amplifier, third output signal wiring whose first end portion is electrically connected to the output terminal of the third high-frequency amplifier and whose second end portion is electrically connected to the third output conversion pin, fourth input signal wiring whose first end portion is electrically connected to the fourth input conversion pin and whose second end portion is electrically connected to the input terminal of the fourth high-frequency amplifier, and fourth output signal wiring whose first end portion is electrically connected to the output terminal of the fourth high-frequency amplifier and whose second end portion is electrically connected to the fourth output conversion pin,
wherein a distance between an inner wall surface of an upper wall of the input waveguide tube and an inner wall surface of a lower wall facing the upper wall is shorter than a distance between an inner wall surface of an upper wall of the output waveguide tube and an inner wall surface of a lower wall facing the upper wall, and a wall thickness of the upper wall of the input waveguide tube is larger than a wall thickness of the upper wall of the output waveguide tube.

14. The power amplification high-frequency circuit device according to claim 11, wherein
the first substrate has: a first input pin insertion hole communicating with a first input pin insertion hole into which the first input conversion pin is inserted and which is formed in the upper wall of the input waveguide tube; a first output pin insertion hole communicating with a first output pin insertion hole into which the first output conversion pin is inserted and which is formed in the upper wall of the output waveguide tube; a second input pin insertion hole communicating with a second input pin insertion hole into which the second input conversion pin is inserted and which is formed in the upper wall of the input waveguide tube; and a second output pin insertion hole communicating with a second output pin insertion hole into which the second output conversion pin is inserted and which is formed in the upper wall of the output waveguide tube,
the first input signal wiring and the second output signal wiring are disposed on a surface of the first insulating substrate while being electrically insulated from a first front surface side shield layer,
the first substrate has: a third input pin insertion hole communicating with a third input pin insertion hole into which the third input conversion pin is inserted and which is formed in the lower wall of the input waveguide tube; a third output pin insertion hole communicating with a third output pin insertion hole into which the third output conversion pin is inserted and which is formed in the lower wall of the output waveguide tube; a fourth input pin insertion hole communicating with a fourth input pin insertion hole into which the fourth input conversion pin is inserted and which is formed in the lower wall of the input waveguide tube; and a fourth output pin insertion hole communicating with a fourth output pin insertion hole into which the fourth output conversion pin is inserted and which is formed in the lower wall of the output waveguide tube, and
the third input signal wiring and the fourth output signal wiring are disposed on a surface of the second insulating substrate while being electrically insulated from a second front surface side shield layer.

15. The power amplification high-frequency circuit device according to claim 11, wherein
widths of the first storage portion and the second storage portion in a direction of a straight line on which the input terminals and the output terminals of the corresponding first high-frequency amplifier and the second high-frequency amplifier are disposed are set to lengths including the corresponding first input pin insertion hole and second input pin insertion hole into which the corresponding first input conversion pin and second input conversion pin are inserted and which are formed in the upper wall of the input waveguide tube, and the corresponding first output pin insertion hole and second output pin insertion hole into which the corresponding first output conversion pin and second output conversion pin are inserted and which are formed in the upper wall of the output waveguide tube, respectively,
the first input signal wiring, the first output signal wiring, the second input signal wiring, and the second output signal wiring are disposed on the back surface of the first insulating substrate,
the first input conversion pin and the second input conversion pin are spring probes which are inserted into the corresponding first input pin insertion hole and second input pin insertion hole into which the first input conversion pin and the second input conversion pin are inserted and which are formed in the upper wall of the input waveguide tube, and are fixed to the upper wall of the input waveguide tube, and distal ends of which are brought into close contact with the corresponding first input signal wiring and second input signal wiring by an elastic force and electrically connected to the first input signal wiring and the second input signal wiring, respectively,
the first output conversion pin and the second output conversion pin are spring probes which are inserted into the corresponding first output pin insertion hole and second output pin insertion hole into which the first output conversion pin and the second output conversion pin are inserted and which are formed in the upper wall of the output waveguide tube, and are fixed to the upper wall of the output waveguide tube, and distal ends of which are brought into close contact with the corresponding first output signal wiring and second output signal wiring by an elastic force and electrically connected to the first output signal wiring and the second output signal wiring, respectively,
widths of the third storage portion and the fourth storage portion in a direction of a straight line on which the input terminals and the output terminals of the corresponding third high-frequency amplifier and fourth high-frequency amplifier are disposed are set to lengths including the corresponding third input pin insertion hole and fourth input pin insertion hole into which the corresponding third input conversion pin and fourth input conversion pin are inserted and which are formed in the lower wall of the input waveguide tube, and the corresponding third output pin insertion hole and the fourth output pin insertion hole into which the corresponding third output conversion pin and fourth output conversion pin are inserted and which are formed in the lower wall of the output waveguide tube, respectively,
the third input signal wiring, the third output signal wiring, the fourth input signal wiring, and the fourth output signal wiring are disposed on the back surface of the second insulating substrate,
the third input conversion pin and the fourth input conversion pin are spring probes which are inserted into the corresponding third input pin insertion hole and fourth input pin insertion hole into which the third input conversion pin and the fourth input conversion pin are inserted and which are formed in the lower wall of the input waveguide tube, and are fixed to the lower wall of the input waveguide tube, and distal ends of which are brought into close contact with the corresponding third input signal wiring and fourth input signal wiring by an elastic force and electrically connected to the third input signal wiring and the fourth input signal wiring, respectively, and
the third output conversion pin and the fourth output conversion pin are spring probes which are inserted into the corresponding third output pin insertion hole and fourth output pin insertion hole into which the third output conversion pin and the fourth output conversion pin are inserted and which are formed in the lower wall of the output waveguide tube, and are fixed to the lower wall of the output waveguide tube, and distal ends of which are brought into close contact with the corresponding third output signal wiring and the fourth output signal wiring by an elastic force and electrically connected to the third output signal wiring and the fourth output signal wiring, respectively.

16. The power amplification high-frequency circuit device according to claim 10, wherein a depth of each of the first storage portion to the fourth storage portion and a width of each of the storage portions in a direction orthogonal to a straight line on which the input terminal and the output terminal of each of the first high-frequency amplifier to the fourth high-frequency amplifier are disposed on a plane including the straight line are each set to a value equal to or less than ½ of a wavelength λ of a frequency of a signal input to each of the first high-frequency amplifier to the fourth high-frequency amplifier.

17. The power amplification high-frequency circuit device according to claim 10, wherein
the first substrate includes: a first front surface side shield layer disposed on a front surface that is one surface of the first insulating substrate, extending to a peripheral portion of the first insulating substrate, and set to a ground potential; a first back surface side shield layer disposed on the back surface of the first insulating substrate, disposed in close contact with a wall surface of an upper wall of the waveguide tube excluding the first storage portion and the second storage portion, extending to a peripheral portion of the first insulating substrate, and set to a ground potential; and a plurality of through holes formed in a peripheral portion surrounding each of the first storage portion and the second storage portion in the first insulating substrate in such a way as to surround a periphery of each of the first storage portion and the second storage portion and electrically connecting the first front surface side shield layer to the first back surface side shield layer, and
the second substrate includes: a second front surface side shield layer disposed on a front surface that is one surface of the second insulating substrate, extending to a peripheral portion of the second insulating substrate, and set to a ground potential; a second back surface side shield layer disposed on the back surface of the second insulating substrate, disposed in close contact with a wall surface of the lower wall of the waveguide tube excluding the third storage portion and the fourth storage portion, extending to a peripheral portion of the second insulating substrate, and set to a ground potential; and a plurality of through holes formed in a peripheral portion surrounding each of the third storage portion and the fourth storage portion in the second insulating substrate in such a way as to surround a periphery of each of the third storage portion and the fourth storage portion and electrically connecting the second front surface side shield layer to the second back surface side shield layer.

18. The power amplification high-frequency circuit device according to claim 10, wherein
a center of each of the first storage portion to the fourth storage portion is located on the output waveguide tube side, and
a length of each of the first output signal wiring to the fourth output signal wiring is a minimum wiring length required for a matching circuit.

19. The power amplification high-frequency circuit device according to claim 10, wherein an interval between the first output conversion pin and the second output conversion pin is narrower than an interval between an output terminal in the first high-frequency amplifier and an output terminal in the second high-frequency amplifier, and an interval between the third output conversion pin and the fourth output conversion pin is narrower than an interval between an output terminal in the third high-frequency amplifier and an output terminal in the fourth high-frequency amplifier.
